(19) United States
(12) Patent Application Publication
(10) Pub. No.: US 2010/0044853 A1
(43) Pub. Date: Feb. 25, 2010

(54) SYSTEM-IN-PACKAGE WITH THROUGH SUBSTRATE VIA HOLES

(75) Inventors: Ronald Dekker, Valkenswaard (NL); Jean-Marc Yannou, Colomby Sur Thaon (FR); Nicolaas J. A. Van Veen, Geldrop (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/523,053

(22) PCT Filed: Jan. 14, 2008
(86) PCT No.: PCT/IB2008/050115

§ 371 Date: Jul. 14, 2009

(30) Foreign Application Priority Data
Jan. 17, 2007 (EP) 07100658.9

(51) Int. Cl. H01L 23/538; H01L 21/50; H05K 1/11

(52) U.S. Cl. 257/692; 438/107; 174/262; 257/E23.174; 257/E21.499

(57) ABSTRACT

The present invention relates to a system-in-package that comprises an integration substrate with a thickness of less than 100 micrometer and a plurality of through-substrate vias, which have an aspect ratio larger than 5. A first chip is attached to the integration substrate and arranged between the integration substrate and a support, which is suitable for mechanically supporting the integration substrate during processing and handling. The system-in-package can be fabricated according to the invention without a through-substrate-hole etching step. The large aspect ratio implies reduced lateral extensions, which allow increasing the integration density and decreasing lead inductances.

### FIELD OF THE INVENTION

The present invention relates to a system-in package and to a method for a fabricating a system-in-package.

### BACKGROUND OF THE INVENTION

US 2002/0084513 A1 describes an assembly of a wafer and an external substrate in the form of a chip or a printed circuit board. The wafer comprises transistors. The external substrate is contacted using a contact structure. For fabricating the contact structure, a trench is fabricated in the wafer by reactive ion etching (RIE) and filled with an insulation layer of BPSG or silicon dioxide, with an electrically conductive layer that allows a later soldering to an external substrate, and, adjacent to the electrically conductive layer, a tungsten core. Subsequently, the wafer is thinned from its backside such that the filling of the hole protrudes from the wafer backside considerably, in a manner that allows using the contact structure as a bump. The insulation layer is therefore partly removed in this step to allow establishing an electrical contact between a contact element of the external substrate and the contact structure.

### SUMMARY OF THE INVENTION

According to a first aspect of the invention, a system-in-package is provided, comprising:

an integration substrate with a thickness of less than 100 micrometer and including a first plurality of through-substrate vias, which have an electrically conductive via core and an aspect ratio larger than 5, and which are configured to electrically connect a first conductive element on the first integration-substrate side with a second conductive element on the second integration-substrate side;

a support, which is attached to the integration substrate on its first integration-substrate side and which is suitable for mechanically supporting the integration substrate; and

a first chip, which is attached and electrically connected to the integration substrate either on its first integration-substrate side, where it is either arranged between the integration substrate and the support or where it forms the support, or

a second chip, which is attached and electrically connected to the integration substrate on its second integration-substrate side.

The system-in-package of the present invention has through-substrate vias in an integration substrate, which has a thickness of 100 micrometer or less. This implies that there is no lateral region, where the integration substrate as such has a thickness of more than 100 micrometer. For the purpose of definition of the thickness of the integration substrate, only the substrate material or wafer material of the integration substrate is considered, and not additional layers or structures deposited on this material on either of the integration-substrate sides. For a through-substrate via typically connects at least one first electrically conductive element on a first integration-substrate side with at least one second electrically conductive element on a second integration-substrate side. Where the conductive elements are formed of layers deposited on the integration substrate, such as metallization layers, their thickness shall not count under the present definition. Nor does the thickness include an extension of solder balls or bumps that can be present on one of the integration-substrate sides, for the purpose of the present definition.

In the system-in-package of the present invention, the through-substrate vias have an aspect ratio larger than five. The aspect ratio of a through-substrate via is the quotient of a depth extension of the through-substrate via between its ends on the first and second integration-substrate sides, and of a lateral extension of the trench that is formed to fabricate the through-substrate in the integration substrate. The lateral extension generally refers to a distance between opposite via-substrate interfaces. The via-substrate interface corresponds to the walls of the original trench. In this context, the via insulation layer is considered a part of the through-substrate via. Therefore, in some embodiments via-substrate interface is formed by the interface between the insulation layer and integration substrate. The lateral trench extension can be derived from the finished integration substrate of the system-in-package, even after filling of the trench during further processing. Suitable analytic techniques are for instance known microscopic methods, like for instance optical microscopy or electron microscopy on a cross section of the integration substrate.

The lateral trench extension of a single trench may vary in the depth direction. For the purpose of definition, in such an embodiment the lateral trench extension shall be considered to be the mean value of the lateral trench extension over along the extension in depth direction.

The system-in-package therefore has through-substrate vias in the integration substrate, which in comparison with the vias of the cited prior art document are particularly short and, due to their high aspect ratio, at the same time have a particularly small lateral extension. In synergy, this combination of features provides a system-in-package that allows combining a very high integration density on the integration substrate with very low parasitic lead inductances of the vias. Both requirements are important for advanced high-frequency applications, like devices for radio-frequency (RF) applications. Both requirements can therefore now be met at the same time.

The inductance of the through-substrate vias scales in a superlinear manner with the length of the through-substrate vias, i.e., their extension in the depth direction, while its dependence on the aspect ratio is only sublinear. Therefore, even though a high integration density is achieved with relatively high aspect ratios of the through-substrate vias, which tends to increase the parasitic lead inductance for a given thickness of the integration substrate, the parasitic lead inductances of the through-substrate vias are at particularly low values. This synergy is achieved by the fabrication technology described herein, which allows providing the integration-substrate with a thickness below 100 micrometer. The low thickness of the integration substrate corresponds with the length of the through-substrate vias.

Integration substrates with a thickness below 100 micrometer bear a very high risk of breakage by the required processing during fabrication, especially during wafer-scale processing, or during dicing, or handling after fabrication, or operation. The present invention overcomes this problem and allows finally achieving the aforementioned advantages by providing a support, which is attached to the integration substrate on its first integration-substrate side and which is suitable for mechanically supporting the integration substrate. The term “suitable” with reference to the support implies a mechanical stability that withstands mechanical stress in an amount that would damage or break an integration substrate of less than 100 micrometer thickness during processing in fabrication, especially during wafer-scale processing, and during handling after fabrication, and during normal operation. The system-in-package of the present invention can thus be produced on wafer scale with good yield and lifetime according to industry standards.

In the following, embodiments of the system-in-package of the first aspect of the invention will be explained. Unless stated otherwise explicitly, the embodiments can be combined with each other.

First, different embodiments will be described that concern arrangements of the first and second chips.

In different alternative embodiments, the system-in-package has either only the first chip, or only the second chip, or both the first and the second chip.

The first chip is in one embodiment attached and electrically connected to the integration substrate on its first integration-substrate side, where it is arranged between the integration substrate and the support substrate. If the second chip is additionally attached and electrically connected to the integration substrate on its second integration-substrate side, a further increased integration density of electronic components contained in the system-in-package can be achieved. An electrical connection between the first and second chips or between components or conductive elements on either integration-substrate side and the chip on the other integration-substrate side can be provided by the through-substrate vias, where required for an application embodiment.

In the following, different embodiments will now be described that further elucidate the combination of integration-substrate thickness and aspect ratio of the through-wafer vias.

The aspect ratio of the through-substrate vias is in some embodiments between 5 and 25, and preferably between 15 and 25. These embodiments are particularly suitable for achieving a high integration density of components on the integration substrate.

Naturally, the depth extension of a through-substrate via is equal or approximately equal to the thickness of the integration substrate. For instance, in one embodiment the integration substrate of the finished system-in-package has a thickness of 40 micrometer, which approximately equals the extension of the through-substrate via in the depth direction. Small difference may result from the presence of additional layers on either the first or the second integration-substrate side.

The lateral extension of the through-substrate via is in some embodiments equal to that of the trench that is formed to fabricate the through-substrate via. In the given example, where the integration substrate has a thickness of 40 micrometer, the lateral extension of the through-substrate via has a value lower than 8 micrometer in any lateral direction, for instance between 8 and 2 micrometer, corresponding to an aspect ratio between 5 and 20.

Speaking of a thickness of 100 micrometer or less obviously does not mean to include the case that the integration substrate is removed completely, i.e., to zero thickness. A lower boundary for the thickness of the integration substrates depends on the particular requirements of an application of the system-in-package. In some embodiments, the thickness is between 10 and 80 micrometer. In some embodiments, the integration substrate has a thickness that just allows accommodating components, such as passive components like trench capacitors or inductors, which are integrated in it. Taking the example of an integration substrate with trench capacitors of 25 to 30 micrometer depth extension, a thickness of the integration substrate of 30 to 40 micrometer forms a lower thickness boundary for the case of this illustrative example. Thus, such embodiments have a thickness of the integration substrate between 30 and 100, 30 and 80, or 30 and 60 micrometer, depending, among other factors, on the depth of the trench capacitors used. In other embodiments, where no trench capacitors are present in the integration substrate, a thickness of only 15 or even less can be suitable. The integration substrate has in some embodiments a thickness between 15 and 40 Micrometer.

As will be described later in more detail when turning to the method aspects of the invention, the through-substrate vias are processed as trench structures in the integration substrate. The term trench structure, as used herein, refers to any suitable shape of recess that is formed in the integration substrate on its first integration-substrate side. A suitable trench structure for a through-substrate via, which is also referred to as a via trench or via trench structure herein, extends through the integration substrate after the processing of the method of the invention. The term trench structure or via trench is in other contexts also used to denote the respective structure after filling, as will be clear from the respective context of usage of the term.

The processing of the trench structures can be differentiated at some point during the processing according to their specific purpose in a desired application in advantageous processing embodiments of the method of the second aspect of the invention. This differentiation is reflected in the claim language by defining different pluralities of trench structures or through-substrate vias.

In one embodiment, a second plurality of trench structures is contained in the integrated substrate, which in comparison with the first plurality of through-substrate vias have smaller depth extensions. The second plurality of trench structures can for instance form trench capacitors.

In one embodiment, the trench capacitors are formed as pillar capacitors. Here, the trench structures have a ring shape, and an alternating layer sequence of conductive and insulating layers is deposited on a pillar or column defined by the trench. A combination of trench capacitors and pillar capacitors is also possible.

In a further embodiment, the system-in-package comprises at least one trench structure in the integration substrate, which has the same depth extension as the through-substrate vias. The at least one trench structure can be used for different functions in application devices, which will be explained by way of different examples in the following.

Such trench structures can for instance be used as electrically floating structures, which serve to electrically isolate components on the integration substrate. Thus, in one embodiment, a subset of the trench structures is formed of fully electrically isolated filled trench structures, and the integration substrate comprises at least one electrical component between a respective pair of neighboring fully electrically isolated filled trench structures. Also, such trench structures can be used to achieve an optical isolation of devices in different areas of the integration substrate.

In one embodiment, the trench structure or the plurality of trench structures forms a section of a cavity in the integration substrate. The cavity can for instance form a part of a micro-electro-mechanical system (MEMS) device on the first integration-substrate side and contain a resonating beam. During the fabrication of a free-standing MEMS device, the trench structure or trench structures can be used as a release trench or access channel for a cavity and/or structural elements of the MEMS device to be created or released by removal of a sacrificial layer through said access channel.

Other functions, for which the at least one trench structure can be used, comprise heat dissipation, grounding, lateral enclosure of a first portion of the integration substrate.

In some embodiments the through-substrate vias have a via-insulation layer, which is arranged to prevent a direct electrical connection between the via core and the integration substrate. This is useful where the integration substrate must be isolated from the via core for proper functioning of an application.

In some embodiments the through-substrate via has the shape of a “hollow” cylinder. This corresponds to a ring shape in a top view. Similar embodiments have a rectangular, quadratic, elliptical or oval ring shape in a top view. Note that the comparison with a “hollow” cylinder is not meant to necessarily imply that there is no material inside the cylinder walls in the present embodiment. In fact, the through-substrate vias are filled in some forms of this embodiment, for instance with the material of the integration substrate, or an insulator material, but with a material different from that of the walls of the “hollow” cylinder.

In fact, a ring-shaped through-substrate via can be used to electrically or optically isolate active or passive circuit elements or devices in the region of the integration substrate, which is arranged inside the ring. The ring-shaped through-substrate vias thus function as an isolation trench in some embodiments.

The fabrication of this useful structure is made possible by the presence of the support. For in the absence of a support, the integration-substrate region surrounded by this isolation trench could detach from the rest of the integration-substrate.

For the purpose of clarity of definition, in this embodiment the term lateral extension does not refer to the distance between outer walls of the hollow cylinder, i.e., the outer diameter of the hollow cylinder, but to the thickness of the wall of the hollow cylinder, i.e., the distance between an inner and an outer wall of the hollow cylinder in a radial direction.

In a further embodiment, a subset of the first plurality of through-substrate vias is electrically connected to a single contact element on the second integration substrate side. The contact element on the second integration-substrate side can for instance be a solder bump. Additionally, an under-bump metallization scheme can be present in some embodiments. Providing a subset of through-substrate vias for connection with the solder bump reduces the electrical resistance and also helps decreasing parasitic lead inductances. This can also be achieved by a through-substrate via that forms a hollow cylinder or a similar shape mentioned before as alternatives for the shape of the through-substrate vias.

Some embodiments comprise an opening in the integration substrate. The opening is open on the second integration substrate side. The opening can for instance be used under strip-lines or an inductor arranged on the first integration-substrate side, to improve the quality of the inductor. An alternative is the use of the opening for a filling with high-resistivity silicon. The opening is in one embodiment used to arrange a third chip therein. This further increases the integration density and variability of the system-in-package.

A second aspect of the invention is formed by a system-in-package that comprises:

an integration substrate with a thickness of less than 100 micrometer and including through-substrate vias that have an electrically conductive via core, of which through-substrate vias a first number are configured to electrically connect a first conductive element on the first integration-substrate side with a second conductive element on the second integration-substrate side, and of which through-substrate vias at least one second through-substrate via is configured to constitute a lateral enclosure for a first portion of the integration substrate;

a support, which is attached to the integration substrate on its first integration-substrate side and which is suitable for mechanically supporting the integration substrate; and

a first chip, which is attached and electrically connected to the integration substrate either on its first integration-substrate side, where it is either arranged between the integration substrate and the support or where it forms the support, or a second chip, which is attached and electrically connected to the integration substrate on its second integration-substrate side.

The system-in-package of the second aspect of the invention shares many of the advantages of the system-in-package of the first aspect of the invention. It has through-substrate vias that serve different functions. In particular, the at least one second through-substrate via is configured to constitute a lateral enclosure for a first portion of the integration substrate. An example of a suitable configuration of the at least one second through-substrate via is a ring-shaped through-substrate via. It can be used to electrically or optically isolate active or passive circuit elements or devices in the region of the integration substrate, which is arranged inside the ring. The ring-shaped through-substrate vias thus function as an isolation trench in some embodiments.

The fabrication of this useful structure is made possible by the presence of the support. For in the absence of a support, the integration-substrate region surrounded by this isolation trench could detach from the rest of the integration-substrate.

In one embodiment of the system-in-package the through-substrate vias are provided with an electrically insulating side wall, and the lateral enclosure is configured to electrically isolate the first portion of the integration substrate. In particular, the lateral enclosure can form at least a part of an electrical shield for a component in or on the first portion of the integration substrate.

Further embodiments of the system-in-package of the second aspect of the invention have additional features, which have been described for embodiments of the system-in-package of the first aspect of the invention.

According to a third aspect of the invention, a system-in-package is provided that comprises:

an integration substrate with a thickness of less than 100 micrometer and including a first plurality of through-substrate vias, that have an electrically conductive via core, of which vias a first plurality are configured to electrically connect a first conductive element on the first integration-substrate side with a second conductive element on the second integration-substrate side;

at least one access channel to a cavity that is defined at and/or on the first integration-substrate side, said access channel extending from the second integration-substrate side parallel to said through-substrate vias;

a support, which is attached to the integration substrate on its first integration-substrate side and which is suitable for mechanically supporting the integration substrate; and

a first chip, which is attached and electrically connected to the integration substrate on its first integration-substrate side, where it is either arranged between the integration substrate and the support or where it forms the support, or a second chip, which is attached and electrically connected to the integration substrate on its second integration-substrate side.

The system-in-package of the third aspect of the invention provides a platform for the fabrication of MEMS devices with cavities integrated into the integration substrate. Embodiments of the system-in-package of the third aspect of the invention have additional features, which have been described for embodiments of the system-in-package of the first aspect of the invention.

A fourth aspect of the invention is formed by a method for fabricating a system-in-package. The method comprises:

providing an integration substrate of a thickness, the integration substrate having a first integration-substrate side and a second integration-substrate side and trench structures, such that in the integration substrate of the finished system-in-package an aspect ratio of the through-substrate vias fabricated from the trench structures is larger than 5, a first plurality of which trench structures is provided with an electrically conductive via core;

attaching a support, which is suitable for mechanically supporting the integration substrate at a reduced integration-substrate thickness of less than 100 micrometer, to the integration substrate on its first integration substrate side;

reducing the thickness of the integration substrate from its second integration-substrate side to a thickness below 100 micrometer, such that only a bottom face of the via cores of the trench structures is exposed;

electrically connecting and attaching a first chip to the integration substrate on its first integration-substrate side, such that the first chip is arranged between the integration substrate and the support, or electrically connecting and attaching a second chip to the integration substrate on its second integration-substrate side.

The processing of the method of the invention comprises a thinning of the integration substrate to a thickness of less than 100 micrometer. Experience shows that thinning the integration substrate down to this range strongly increases the risk of substrate breakage during thinning, later processing or handling of the integration substrate.

This problem is not considered at all in US 2002/0084513 and limits the applicability of the method known from this document to an integration-substrate thickness well above 100 micrometer. In this thickness range, however, it is impossible with the processing techniques described in US 2002/0084513, namely, reactive ion etching, to fabricate through-substrate vias with an aspect ratio larger than 5.

This problem is overcome by the method of the present aspect of the invention by attaching a support to the integration substrate on its first integration substrate side. The support is suitable for mechanically supporting the integration substrate at a reduced integration-substrate thickness of less than 100 Micrometer. That means, it provides the mechanical stability required to avoid breakage during thinning, later processing, and handling of the integration substrate. Another advantage of the support is that it helps dealing with high thermo-mechanical stress in the field operation on the surface of an ultra thin substrate (lower than 100 μm), possibly inducing cracks in the substrate die.

This processing turns away from the concept of fabricating a single through-substrate via to function also as a solder bump. Instead, during processing, only a bottom face of the via cores via trench structures is exposed. This processing relaxes the requirements of mechanical stability against lateral stress applied to the through-substrate via and allows fabricating the through-substrate vias with a reduced lateral extension. This in turn allows increasing the integration density on the integration substrate, including a fabrication of a larger number of through-substrate vias without increasing area consumption on the integration substrate.

Therefore, not only can the integration density be driven to very high values, but also can parasitic lead inductances of the through-substrate vias be made very low.

In one embodiment, this is made possible without having to use though-wafer via holes with a conductive copper core. Instead, tungsten is used for the via core in this embodiment. Being able to avoid the use of copper is a great advantage in the present context. The use of copper would require the provision of a copper diffusion barrier in the via holes. From a processing point of view, this is undesirable. For at the moment, this can only be achieved using atomic layer deposition (ALD) equipment and therefore involves an extremely low deposition rate. This increases processing costs. Furthermore, copper processing and the processing of copper-containing integration substrates, such as silicon wafers, is usually also undesirable due to possible contaminations introduced by the presence of copper. Additionally, fully copper-filled via holes could pose a reliability risk due to differences in thermal-expansion coefficients in comparison with surrounding material, such as silicon. In contrast, being able to stay with established processing technology allows using for instance tungsten as a via core material. Tungsten can be deposited fast, for instance by chemical vapor deposition (CVD) or plasma-enhanced (PE)CVD.

Note that the above considerations shall not be understood as restricting the scope of the invention via plugs with materials other than copper in the via core. Copper does have advantages, for instance a high conductance. The extra cost of an introduction of Cu may well be outweighed by its advantages for a particular application in other embodiments.

The support is suitably an insulating substrate, such as a glass or silicon substrate, that is attached to the integration substrate prior to its thinning. Alternatively, the support may be an over-moulded encapsulation, for instance on the basis of an epoxy material, such as usually applied in packaging.

Another embodiment comprises the provision of the integration substrate with a temporary support on its second integration side. Thus, in one embodiment, providing the integration substrate comprises providing an integration-substrate assembly with the integration substrate having an integration-substrate thickness below 100 micrometer and a temporary support attached thereto. In this embodiment, the integration substrate has already been provided with the vias and has been thinned to a suitable thickness. This temporary support may be removed after the assembly of the chip on the first integration side and the provision of the support. Thus, reducing the thickness of the integration substrate from its second integration-substrate side to a thickness below 100 micrometer comprises removing the temporary support. The advantage hereof is that one need not perform etching and deposition steps after assembly. This reduces risks and is more in line with the usual division between front end and back end processing.

Note that the step of providing an integration substrate with a first electrically conductive element is in one embodiment to be understood as comprising a single step, in which an integration substrate is provided, which has a prefabricated first electrically conductive elements. However, the step of providing an integration substrate with a first electrically conductive element is in another embodiment to be understood as comprising a processing, in which the first electrically conductive element that is provided on the first integration-substrate side is fabricated during later processing, after any of the further steps comprised by the method of the first aspect of the invention. As an example for this latter processing, the first electrically conductive element can be fabricated after the formation of the trench structures. However, it must be fabricated before the step of attaching the support.

In one embodiment, fabricating the first plurality of trench structures is performed employing reactive ion etching (RIE). RIE has proven very useful in fabricating trench structures with lateral extensions, which are substantially reduced in comparison with standard through-substrate via holes as known from prior-art processing techniques. The disadvantage of these prior-art processing techniques is that the use of RIE makes the fabrication of through-substrate via holes with larger depth and lateral extensions a relatively slow and expensive process. The use of RIE in the context of the processing of the method of the first aspect of the invention, however, enables reducing the etching time as much as possible. For the depth and the lateral extensions of the trench structures are significantly reduced due to the decreased thickness of the integration substrate in the finished system-in-package, and due to the large aspect ratio of the through-substrate vias.

In some embodiments, trench structures for through-substrate vias and other trench structures, such as trench capacitors or isolation trenches, are fabricated in a single step, which typically is an RIE etching step. One particular embodiment comprises a fabrication of a second plurality of trench structures in the integration substrate with smaller depth extensions in comparison with the first plurality of trench structures, by reactive ion etching. The first and second plurality of trench structures are etched concurrently, and etching comprises forcing smaller lateral extensions for the second plurality of trench structures than for the first plurality of trench structures.

This embodiment makes use of the finding that RIE tends to etch wider trenches faster than narrower trenches. Therefore, this effect can be employed to create two depth levels of trenches in one etching step by forcing two different lateral extensions for the first and second pluralities of trench structures. The different lateral extensions can be forced for instance by providing suitable lateral extensions of mask openings for the etching step.

The second plurality of trench structures can for instance be used for fabricating trench capacitors in later processing steps. This is a particularly simple processing for such different structures. However, it should be noted that there is no requirement to fabricate trench structures for different purposes.

In a further embodiment, the thinning of the integration substrate comprises:

mechanically grinding the integration substrate from the second integration-substrate side to a thickness that just avoids exposure of the first plurality of trenches;

spin-etching the integration substrate using a first etching agent that leaves the via insulation layer intact;

removing a part of the via insulation layer by etching, using a second etching agent that leaves the via core intact.

This processing allows a very precise control of the material removal on the second integration-substrate side.

A particularly high integration density is achieved in the method of the invention by attaching a first chip on the first integration-substrate side of the integration substrate. The first chip on the first integration-substrate side is in the processing of the present invention preferably thinned before attaching the support. The thinning of the first chip makes adhesive bonding of a support substrate easier. A suitable thickness of the first chip after this thinning step is for instance 20 to 30 Micrometer. This thickness can for instance be achieved by grinding after attaching the first chip to the integration substrate. Attaching the first chip typically involves solder bumping of the first chip and an underfilling step.

In a further embodiment, attaching the support comprises:

depositing an adhesive layer that can be cured by irradiation with ultraviolet light on the first integration-substrate side;

positioning a support substrate on the adhesive layer;

irradiating the adhesive layer with ultraviolet light.

The use of an adhesive layer, which can be cured in UV light, avoids heating steps required for other adhesive materials, which could negatively affect the system-in-package. In this context, the use of glass as a support substrate is advantageous, because suitable glass materials can be chosen that are transparent to the UV irradiation used for curing the adhesive layer. An alternative to glass is wafer-level compression molding of epoxy resin.

In a further embodiment, a step of fabricating an opening in the integration substrate is performed. The opening is open on the second integration substrate side. The opening can for instance be used under an inductor or strip-lines to improve the quality of the inductor. An alternative is the use of the opening for a filling with high-resistivity silicon.

The opening can be fabricated by reactive ion etching. Preferably, the etching of the opening is performed at the end of the processing of the system-in-package, in order to keep the integration substrate planar as long as possible and to thus facilitate the processing.

The opening created this way may serve other purposes, such as for positioning a second chip within the opening. This way, a chip stacking on three levels is made possible.

A fifth aspect of the invention is formed by a method for manufacturing a system-in-package. The method comprises the following steps:

providing an integration substrate having a first integration-substrate side and a second integration-substrate side and a thickness and comprising a first plurality of trench structures and a second set of at least one trench structure, all of which trench structures are provided with an electrically conductive via core, of which the first plurality of trench structures is configured for a signal transmission function and of the which second set of trench structures is configured for another function, which is one of a heat dissipation, grounding, lateral enclosure of a first portion of the integration substrate, and constituting at least one access channel for a cavity to be created by removal of a sacrificial layer through said access channel;

attaching a support, which is suitable for mechanically supporting the integration substrate at a reduced integration-substrate thickness of less than 100 micrometer, to the integration substrate on its first integration substrate side;

reducing the thickness of the integration substrate from its second side to a thickness below 100 micrometer, such that only a bottom face of the via cores of the second plurality of trench structures is exposed; and

electrically connecting and attaching a first chip to the integration substrate on its first integration-substrate side, such that the first chip is arranged between the integration substrate and the support, or electrically connecting and attaching a second chip to the integration substrate on its second integration-substrate side.

The method forms a platform for integrating trench structures for many different application purposes in a unified processing scheme.

A seventh aspect of the invention is formed by an integration substrate including trenches that have an electrically conductive trench core, of which trenches a first plurality are electrically connected with a first conductive element on the first integration-substrate, and of which trenches at least one second trench is configured to constitute a lateral enclosure for a first portion of the integration substrate.

the integration substrate of this aspect of the invention forms an intermediate product of the processing of one of the method aspects of the invention.

Embodiments of the method of the fifth aspect of the invention comprise additional features of embodiments that have been described on the basis of the method of the fourth aspect of the invention.

Further preferred embodiments of the invention are defined in the dependent claims. It shall be understood that the method of the first aspect of the invention and the system-in-package of the second aspect of the invention have similar and/or identical preferred embodiments, as defined herein and in the dependent claims.

### BRIEF DESCRIPTION OF THE DRAWINGS

The invention will now be explained in more detail with reference to the drawings in which:

FIGS. 1 to 17 show schematic, cross-sectional views of a system-in-package during different stages of a first embodiment of a fabrication method.

FIG. 18 shows a schematic cross-sectional view of a first embodiment of a system-in-package.

FIGS. 19 to 29 show schematic, cross-sectional views of a system-in-package during different stages of a second embodiment of a fabrication method.

FIG. 30 shows a schematic cross-sectional view of a system-in-package according to a second embodiment.

FIGS. 31 to 39 show schematic, cross-sectional views of a system-in-package during different stages of a third embodiment of a fabrication method.

FIG. 40 shows a schematic cross-sectional view of a system-in-package according to a third embodiment.

### DETAILED DESCRIPTION OF EMBODIMENTS

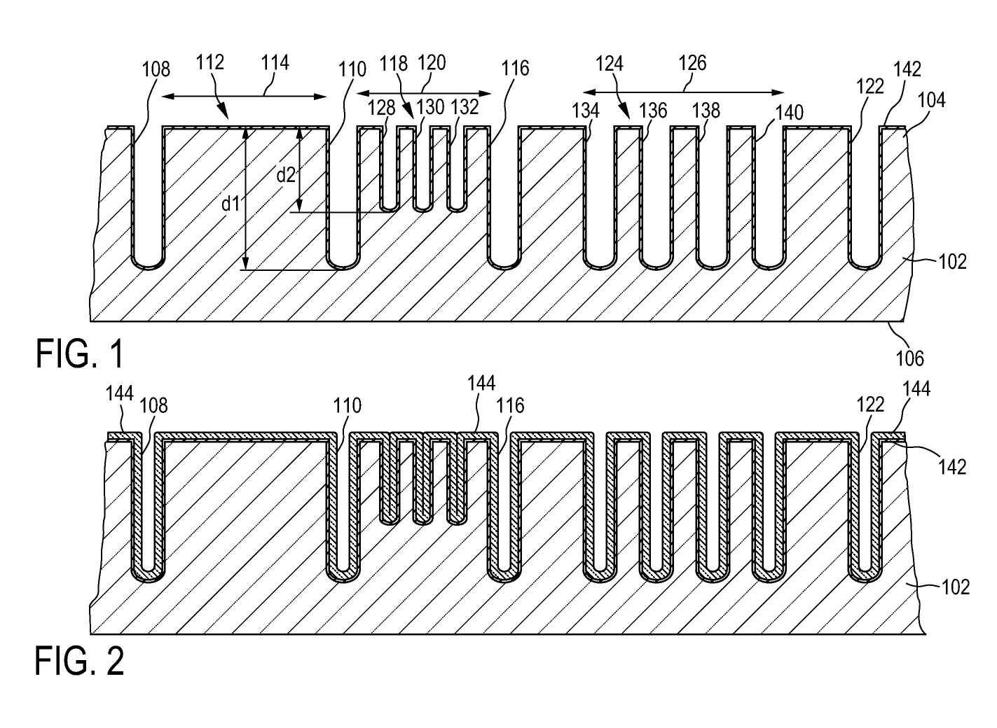

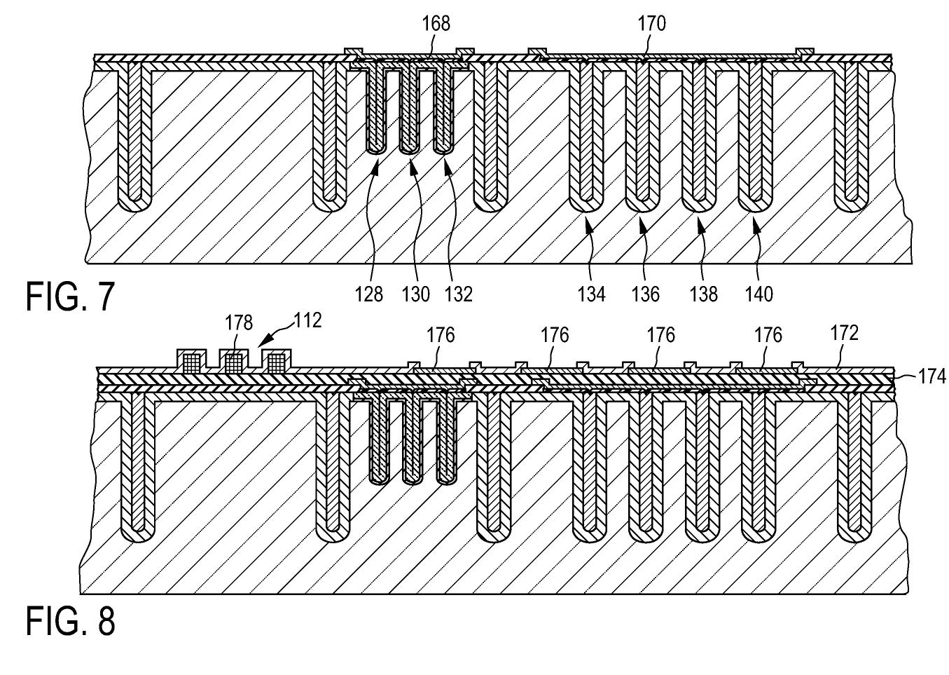

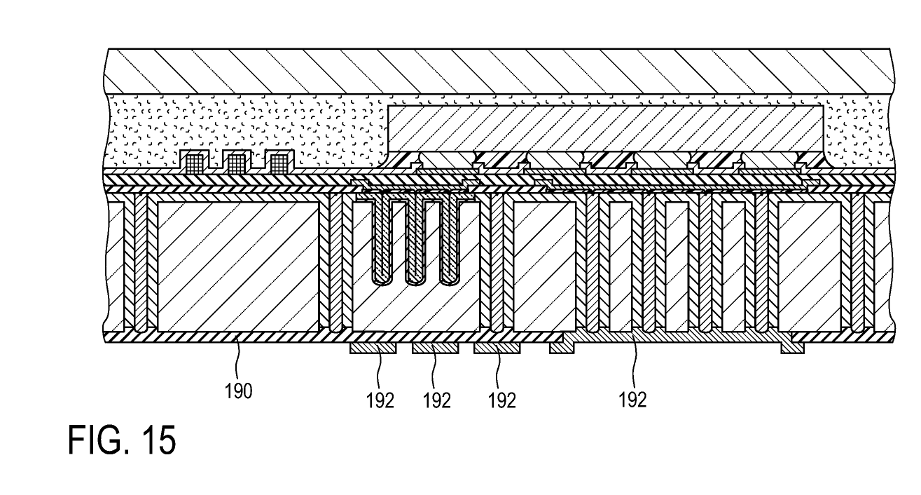

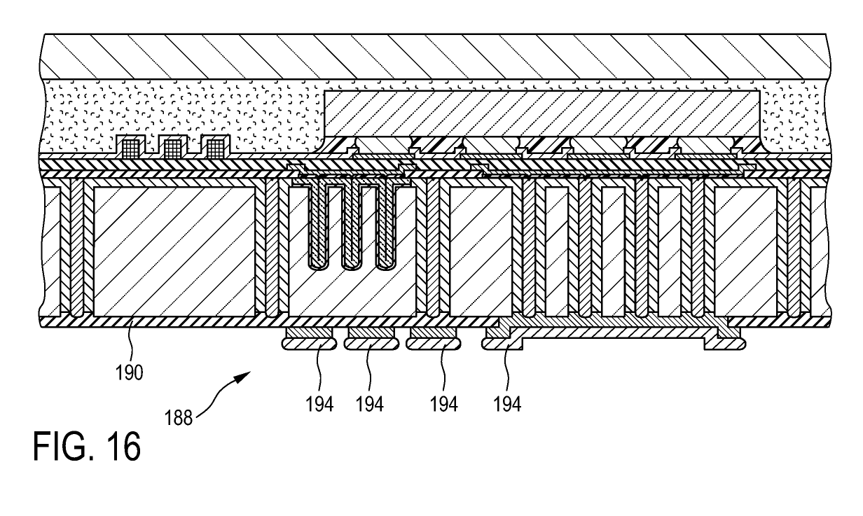

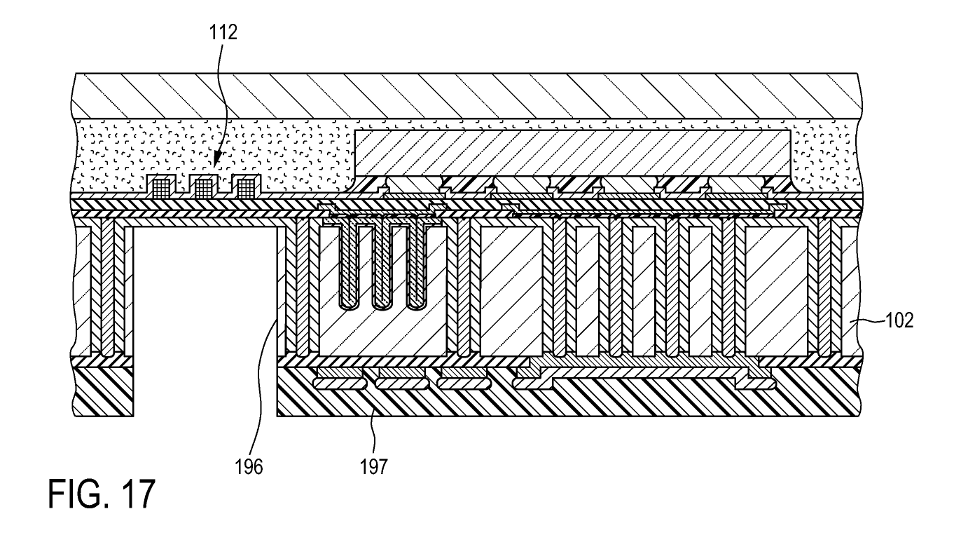

FIGS. 1 to 17 show a schematic, cross-sectional views of a system-in-package during different stages of an embodiment of a fabrication method.

FIG. 1 shows a carrier or integration substrate 102. The integration substrate 102 has a first integration-substrate side 104 and a second integration-substrate side 106. The first integration-substrate side will herein after also be referred to as the front side, and the second integration-substrate side will also be referred to as the back side. However, use of the terms “front side” and “back side” shall not be understood as a restriction to a specific arrangement of the integration substrate.

On the first integration-substrate side 104, a number of trenches has been fabricated at the processing stage shown in FIG. 1. Trenches 108 and 110 laterally define an inductor area 112, the lateral extension of which is indicated by a double arrow 114. The trenches 110 and 116 laterally define a capacitor area 118, the lateral extension of which is indicated by a double arrow 120. The trenches 116 and 122 laterally define a through-substrate or, in other words, through-wafer via array 124, the lateral extension of which is indicated by a double arrow 126. The trenches 108, 110, 116, and 122 are also referred to as isolation trenches.

In the capacitor area 118, three capacitor trenches 128, 130, and 132 have been formed. The number of capacitor trenches is of purely exemplary nature. Of course, also the lateral extension of the capacitor area is chosen here only for the purposes of graphical representation. It is understood that the lateral extension of the capacitor area 118 and the number of capacitor trenches is to be chosen according to the needs of a particular application. The fabrication method described here does not impose limits on the lateral extension or the number of capacitor trenches.

The through-wafer via array 124 is shown to have four via trenches 134, 136, 138, and 140. The number of via trenches and the lateral extension of the through-wafer via array are of purely exemplary nature.

In the present embodiment, the integration substrate 102 is formed by a silicon wafer. However, this is not a necessary requirement. Other substrate materials can be used as well for the integration substrate 102. Suitable examples are for instance InP, GaN, AlN, Glass, GaAs, etc. In one embodiment of a processing method, all trenches provided at the present processing stage have been fabricated in one reactive ion etching (RIE) process. This processing makes use of the fact that in a RIE process like the Bosch process wider trenches tend to be etched faster than narrower trenches. It is thus achieved that two different depths d1 and d2 of trenches can be fabricated in one etching step by using two different trench widths. For instance, suitable etching conditions can be found to achieve a trench depth d2 of 27 μm with a trench width of 1.5 μm, while a trench width of 5.0 μm can be used to achieve a trench depth d1 of 47 μm. However, the trenches may in an alternative embodiment be etched separately, for instance in view of process control requirements. As a further alternative, the trenches may be etched partially simultaneously, for instance by etching the isolation trenches 108, 110, 116, and 122, as well as the via trenches 134 to 140 to a certain depth in a first step, using an auxiliary masking layer. In a second step, the etching of the isolation trenches and the via trenches is continued and at the same time the capacitor trenches 128 to 132 are etched, after removing the auxiliary masking layer.

FIG. 1 shows the integration substrate 102 at a later processing stage, in which a dielectric layer 142 has been deposited or grown. A suitable fabrication technique for the isolation layer is for instance the growth of a thermal oxide. The oxide layer 142 covers the front side 104 of the integration substrate 102 and is also present at side walls and bottom faces of the trenches. Note that intermediate steps involving the removal of a resist etc. have not been illustrated.

In a subsequent processing stage, which is shown in FIG. 2, a phosphorous-doped polysilicon layer 144 has been deposited to such a thickness that it completely fills the capacitor trenches 128 to 132. The isolation trenches 108, 110, 116, and 122 are not completely filled by the P-doped polysilicon layer 144. The P-doping can be performed in-situ during the deposition of the polysilicon layer.

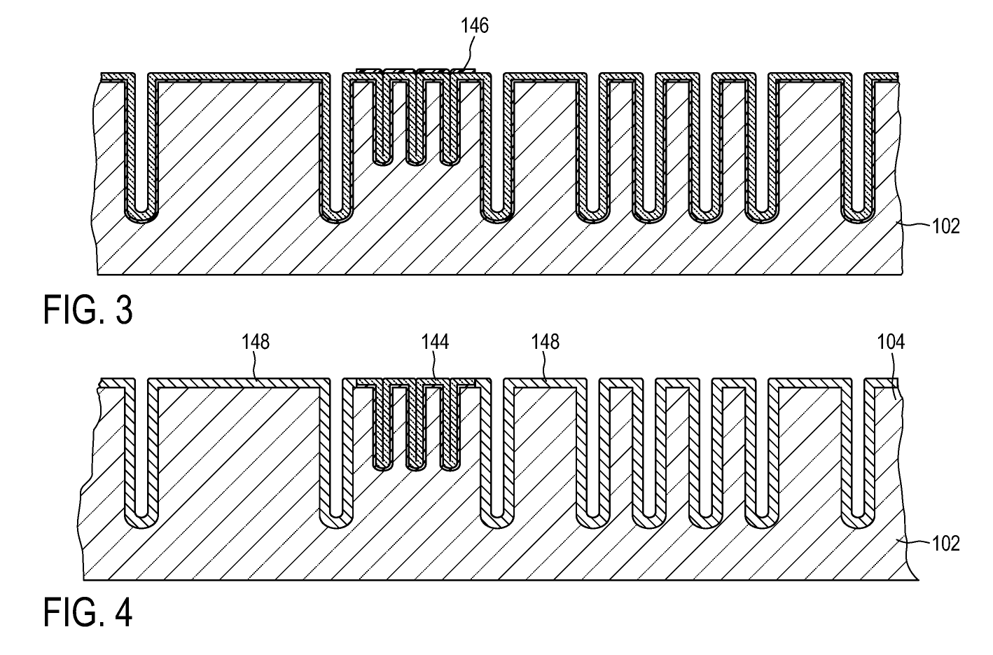

Subsequently, as shown in FIG. 3, a silicon nitride layer 146 is deposited and patterned for definition of capacitors in the capacitor area 118. The silicon nitride layer 146 can be deposited by low-pressure chemical vapor deposition (LPCVD).

The silicon nitride layer 146 is used as a mask during a subsequent thermal oxidation step, in which the exposed polysilicon-layer regions, which are not covered by the silicon nitride layer 146, are oxidized outside the capacitor area 118. In this “LOCOS style” oxidation step, an oxide layer 148 of approximately 1 to 1.5 μm thickness is formed, cf. FIG. 4. The oxide layer 148 extends on the front side 104 of the integration substrate 102 and in the isolation and via trenches.

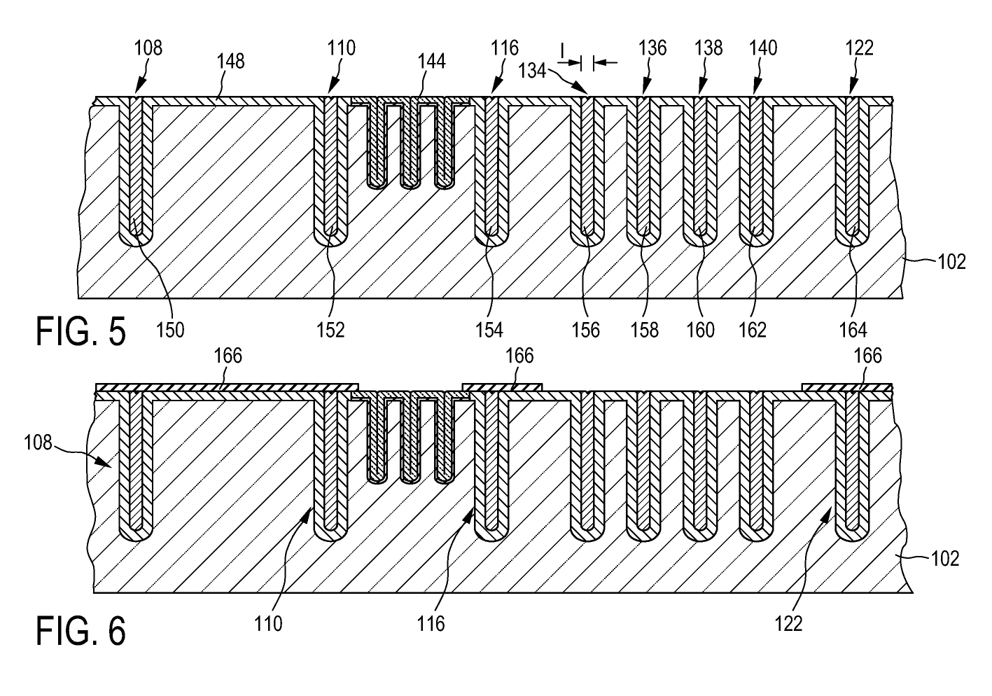

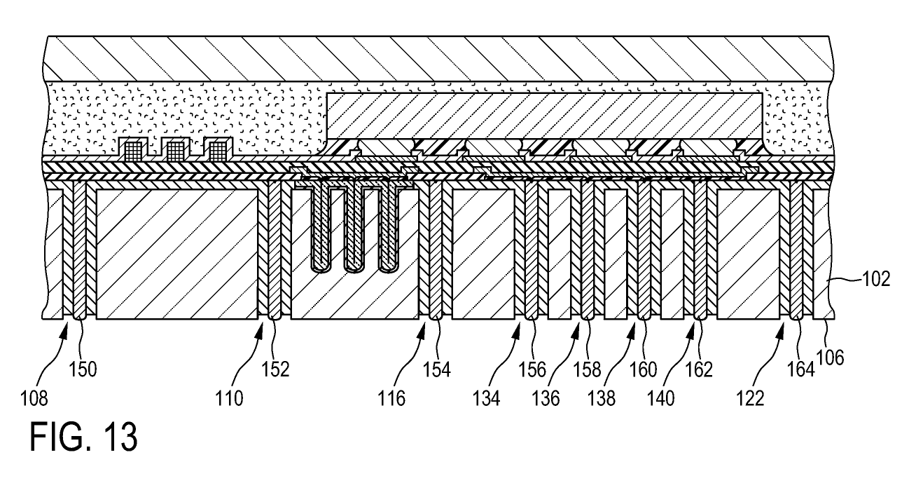

Subsequently, as shown in FIG. 5, the isolation trenches 108, 110, 116, and 122 and the via trenches 134 to 140 are filled with tungsten. This can for instances be achieved by plasma enhanced chemical vapor deposition. The tungsten, which is in this step deposited on the surface of the integration substrate 102 is removed. This can be achieved for instances by an etching step. A suitable etchant is for instance SF₆. An alternative removal method is chemical-mechanical polishing (CMP). The tungsten filling of the isolation trenches 108, 110, 116, and 122 in the via trenches 134 to 140 forms an electrically conductive via core 150.1 to 164.1 for vias 150 to 164 (see FIG. 13), while the oxide layer 148 that separates the via core from the substrate forms a via insulation layer, which prevents a direct electrical convention between the via core and the integration substrate 102. The via cores have a lateral extension 1 of less than 3 μm. Note that the via cores 150.1 to 164.1 are completely filled with tungsten. A partial filling of the trenches with tungsten is not advisable because tungsten layers posses high levels of stress.

In a subsequent processing step, the result of which is shown in FIG. 6, a dielectric layer 166 is deposited and patterned to cover the isolation trenches 108, 110, 116 and 122. The dielectric layer 166 can for instances be deposited by PECFD. The dielectric layer can for instance be made of silicon dioxide.

The patterning of the dielectric layer 166 allows contacting the capacitor trenches 128 to 132 and the via trenches 134 to 140 with an electrically conductive contact structure 168 and 170, respectively. Note that in an embodiment not shown here, some of the tungsten via cores 134 to 140 may be kept floating. Such trenches can be used to electrically isolate the different components in the process.

Subsequently, after the deposition of the first metal layer comprising the contacts 168 and 170, the fabrication of an interconnect stack 172 proceeds in a well-known manner. The interconnect stack 172 is schematically represented in FIG. 8 by two interconnect levels with an intermediate interlevel dielectric layer 174 and a second metal level 176. However, any suitable number of interconnect levels can be chosen for the particular application. An inductor 178 has been fabricated on the second interconnect level 176 in the inductor area 112.

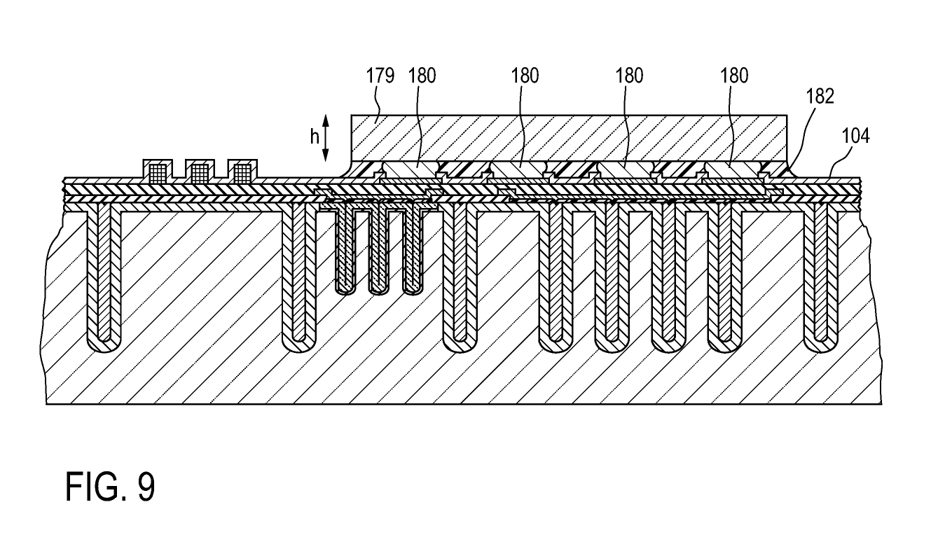

Subsequently, as is shown in FIG. 9, a chip 179, which herein is also referred to as a first die, has been attached to the integration substrate by solder bumping. The solder bumps 180 are connected to the contacts 176 on the second interconnect level. An under filling 182 serves to protect and isolate the free space underneath the chip 179.

The thickness h of the chip 179 is reduced by grinding to approximately 20 to 30 μm before attaching it to the substrate. Providing an underfilling of the chip 179 makes it easier to attach a support substrate in a subsequent step. The chip may form or contain a passive device, a sensor, an actuator, an optoelectronic device, a microlens, or integrated circuitry, in which case it is referred to as an active die. The chip 179 may be made from silicon or other substrate materials, as mentioned before for the integration substrate, i.e. InP, GaN, AlN, Glass, GaAs, to name examples.

In the context of the attachment of the chip 179 on the integration substrate 102, use can be made of a self-aligning action of solder bumps. When the solder becomes liquid, surface tensions will cause an exact adjustment of a chip over the apposing contacts (bond pads). This effect becomes stronger if the number of bond pads increases. In principal, Micrometer-accurate alignment is possible this way.

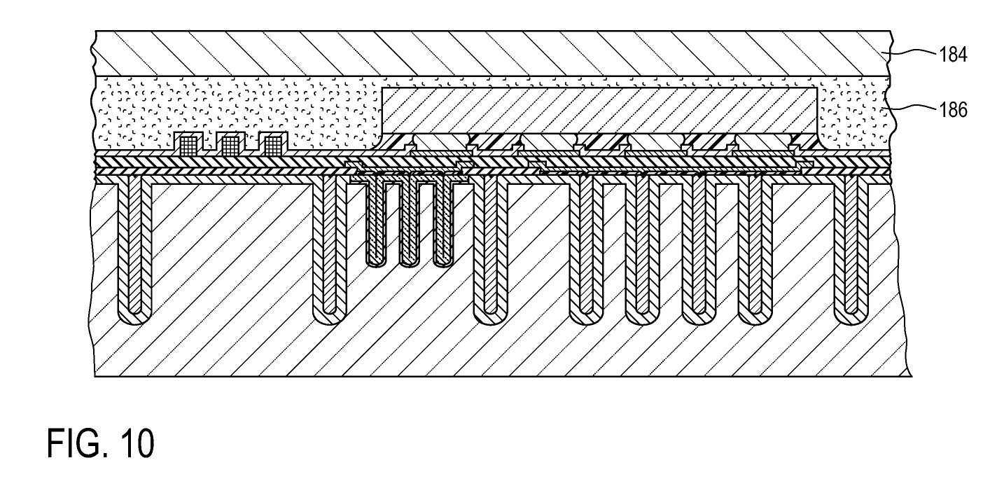

Subsequently, as shown in FIG. 10, a support 184 is attached to the integration substrate 102 by means of adhesive wafer bonding. An adhesive layer 186 is provided, which is cured using UV illumination. This way, a heating of the structure is avoided. A suitable material for the substrate carrier is glass. Glass is isolating, transparent and cheap.

An alternative suitable support can be provided in the form of an over-mould, for instances an epoxy over-mould. It should be noted that the reduced thickness of the chip 179 makes it easier to attach the support substrate 184 in an adhesive waver bonding process.

Subsequently, the integration substrate 102 is thinned, for instance by mechanical grinding to a thickness, at which the deepest trenches, which are the isolation trenches 108, 110, 116 and 122 and the via trenches 134, 136, 138, und 140 are not exposed on the backside 106 of the integration substrate 102. Note that the cross-sectional view of the present Figs. leaves some ambiguity with respect to the lateral structure of the isolation trenches, which in fact reflects different embodiments. Reference labels 108, 110 refer in one embodiment to separate isolation trenches. In another embodiment with the same cross-sectional view, reference labels 108 and point to different sides of a single, coherent, ring-shaped or, in other words, annular isolation trench. The same holds for the reference labels 110 and 116, which in one embodiment can be configured in annular shape, as seen in a top view. Of course, the shape can also have a rectangular outline, which would make it possible to combine two closed isolation trenches shown under reference labels 108, 110, and 116, which share the section 110.

It is suitable to leave a distance y of approximately 20 micrometer between the bottom of the deeper trenches and the backside surface 106 of the integration substrate.

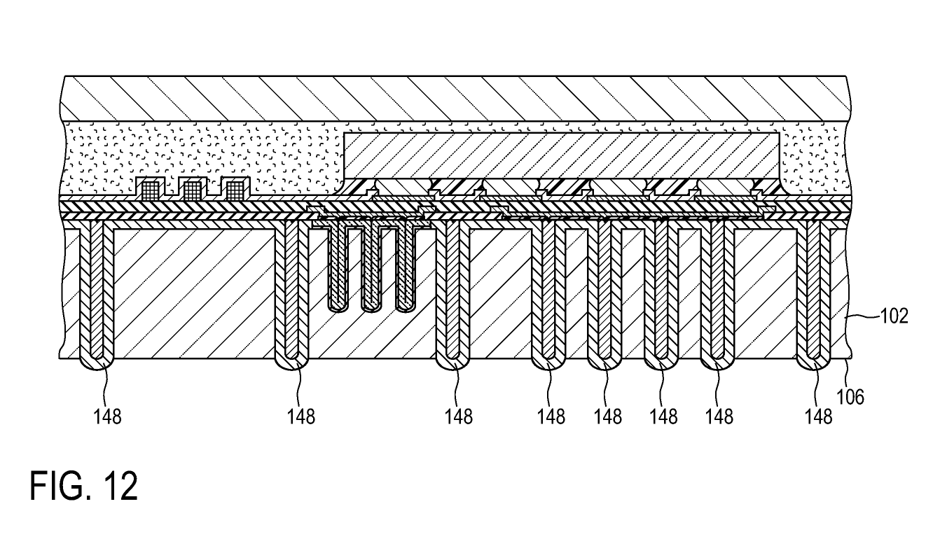

Subsequently, as shown in FIG. 12, grinding damage is removed by spin etching the integration substrate in a suitable etching solution, for instance HF/HNO₃. This etch is selective enough towards silicon dioxide, so as to leave the isolation layer 148 in the trenches intact. Therefore, at the present processing stage, the different sections of the isolation layer 148 at the bottom of the trenches are protruding from the backside 106 of the integration substrate 102.

In a subsequent processing step, the result of which is shown in FIG. 13, the isolation layer 148 is removed from the bottom of the trenches. This can suitably be achieved by wet etching in a buffered oxide etch, which does not attack the tungsten via cores 150.1 to 164.1. Therefore, these tungsten via cores are exposed at the backside 106 of the integration substrate 102, thus becoming through-substrate vias 150 to 164. The isolation layer 148 is used for insulating side walls 150.2 to 164.2 of the through-substrate vias.

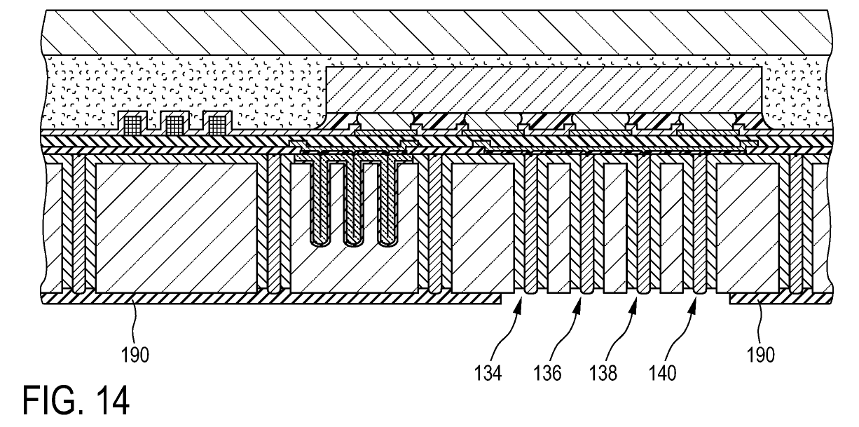

Subsequently, as shown in FIG. 14 to 16, a backside metallization scheme 188 is formed, which involves the formation and patterning of an insulation layer 190, the formation of bond pads 192 in openings of the isolation layer 190 and/or on top of the isolation layer, and the formation of solder bumps 194 on the contact areas 192.

In a subsequent step, a recess 196 is formed in the integration substrate 102 underneath the inductor area 112. The recess 196 can for instances be formed by removing some integration-substrate material in a deep RIE process, for instance using a Bosch process. Note that in comparison with known processing techniques, the etching step has been postponed to the end of the processing. This allows keeping the integration substrate 102 planar as long as possible and facilitates the processing.

Instead of forming the recess 196, an alternative choice is to use a high-resistivity silicon integration substrate 102. However, high-resistivity silicon substrates are expensive.

After stripping a resist layer 197 used during the RIE process, a backside chip 198 is attached to the integration substrate 102 by solder bumping to the solder bumps 194. Furthermore, solder bumps 199 are placed on the backside 106 of the integration substrate 102, thus enabling an electrical contact between circuit elements on the front side 104 of the integration substrate, circuit elements on the chip 179 on the front side of the integration substrate, circuit elements on the backside chip 200, and an external substrate, such as for instances a printed circuit board.

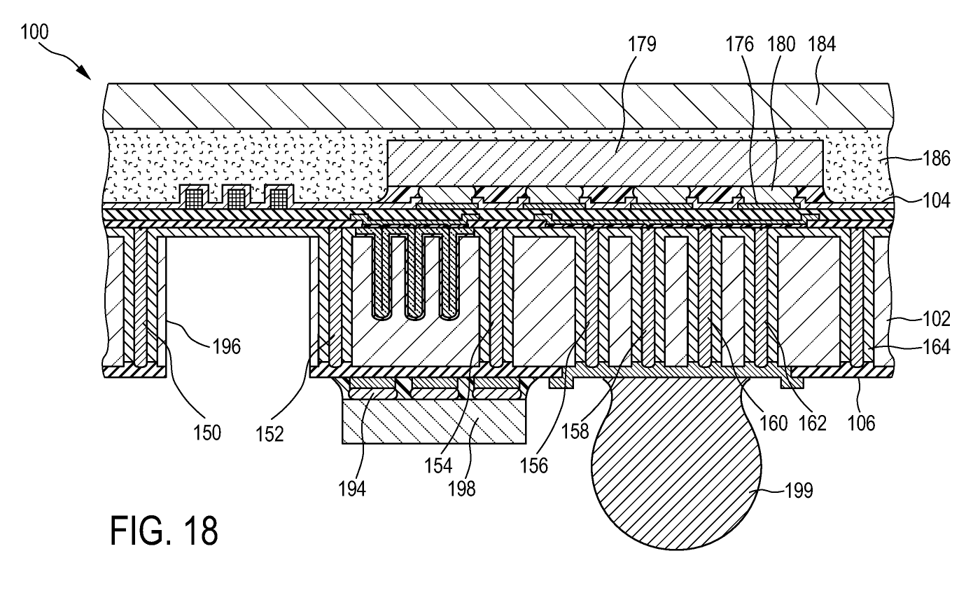

The described processing has the advantages that no through-substrate hole etching is required. The through-wafer via holes and the trench capacitors are etched in a single etching step. The use of copper as a trench filling or via core material can be avoided. This is due to the fact that the vias can be formed by a deep RIE process with subsequent filling of the substrate. Therefore, a standard tungsten filling can be used. The system in package of FIG. 18 further achieves a full dielectric device isolation by the isolation trenches, which are formed concurrently with the via trenches. The isolation trenches at the same time can serve to provide optical isolation of device in separate silicon islands.

Note that in the process described a glass substrate is used as a support substrate. In many aspects, glass is convenient for this application. It is cheap, available with wafer size, isolating, and transparent, thus also allowing a UV curing. However, glass is not the only suitable support substrate. Other support substrates may be used such as silicon wafers, GaAs-wafers, ceramic or polymer substrates. Additionally, a molding technique may be used to form the support. Epoxy moulds are widely used in the integrated circuits industry, and silicon filling, a thermal expansion approaching that of silicon may be realized. The support substrate is in some embodiments removed, for instances by using thermal or UV releasing adhesives or tapes.

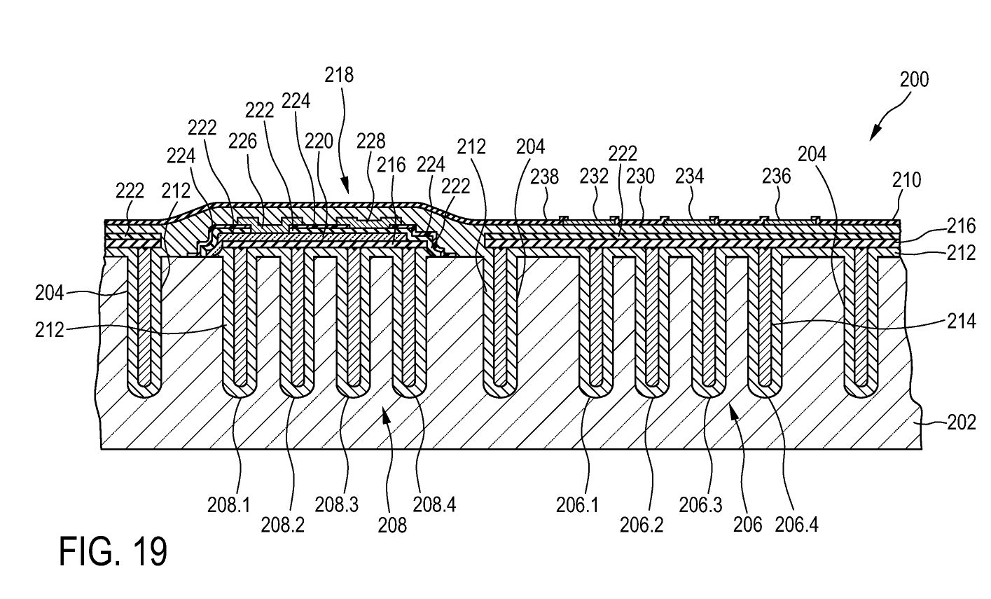

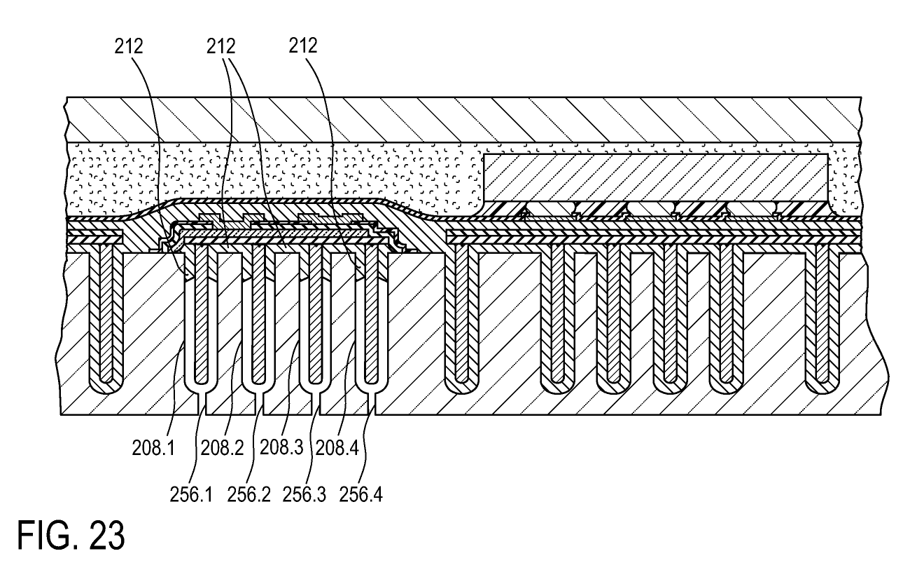

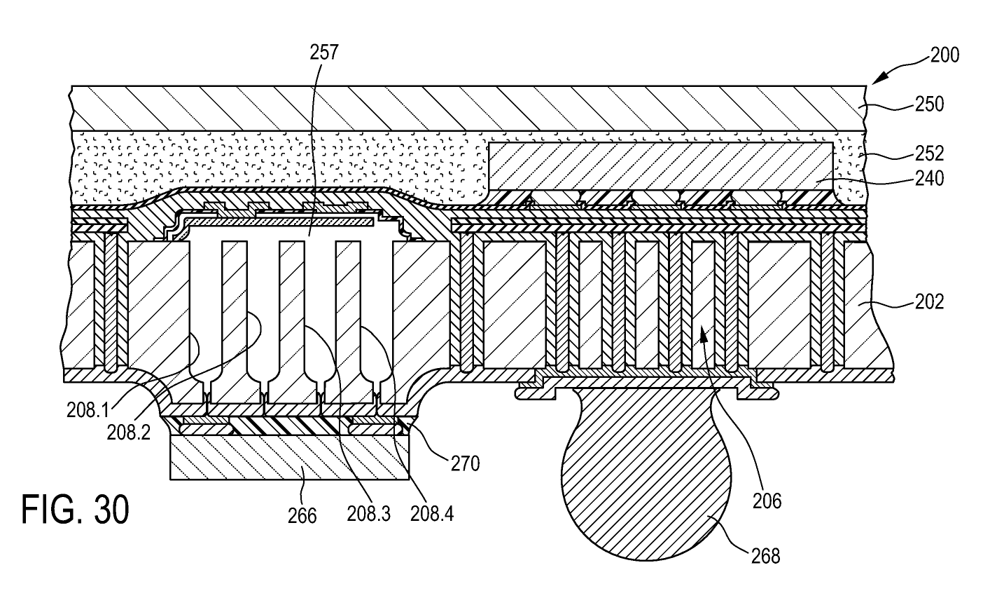

FIGS. 19 to 29 show schematic, cross-sectional views of a system-in-package during different stages of a second embodiment of a fabrication method. FIG. 30 shows a schematic cross-sectional view of a system-in-package according to a second embodiment.

The present embodiment serves to illustrate the suitability of the processing of the invention for the fabrication of a MEMS device. In principle, the processing is applicable to any free standing MEMS device. For the purpose of illustration, the present embodiment uses a simple resonating-beam device, in order to keep the structural detail in the figures as simple as possible.

The processing of the system-in-package 200 starts with the fabrication of an integration substrate 202 in a manner, which is similar to that described in the context of the FIGS. 1 to 8. The following description concentrates on the differences between the resulting structures of FIG. 8 and FIG. 19. The integration substrate 202 of FIG. 19 has an isolation trench 204, which surrounds device to be further described for complete dielectric isolation.

An array 206 of trenches contains trenches 206.1 to 206.4, which shall serve as through-substrate vias. Note, for simplicity, the through-substrate vias will be given the same reference labels as the trenches of the present processing stage.

Furthermore, the integration substrate 202 contains a release-trench array 208 with release trenches 208.1 to 208.4.

As can be seen in FIG. 19, the general structure of the trenches and trench-arrays 204, 206, and 208, respectively, is identical. The trenches were etched by RIE. Capacitor devices, which are not shown in the figures but may well be present, depending on a particular application, were etched in the same etching step. Different widths of mask openings for the etching process resulted in different depths of the trenches, as has been described in more detail in the context of FIG. 1.

Subsequently, in-situ doped poly-silicone was deposited in the trenches and on a first integration substrate side 210, followed by a LPCVD deposition of Si₃N₄ and patterning by wet etching. A subsequent “LOCOS”-type oxidation of the poly-silicon and a wet etching of the Si₃N₄ layer resulted in a trench isolation layer 212 of thermal silicon dioxide, which extends in all trenches and on sections of the first integration-substrate side 210, as can be seen in FIG. 19.

The trenches were then filled with tungsten by CVD, followed by a tungsten back-etch resulting in tungsten trench fillings present in all trenches shown in FIG. 19 and indicated by way of example using the reference label 214. The trench fillings have a lateral extension of less than 3 μm. The subsequent processing included the deposition and patterning of a dielectric layer 216, for instance TEOS.

The dielectric layer 216 and the underlying oxide layer 212 were then patterned in preparation of the particular structure required by a specific MEMS structure 218, which in the present example is a resonating-beam device. Then, poly-silicon was deposited and patterned to form a resonating beam 220. Then, an upper release isolation layer 222 was deposited and structured. The upper release isolation layer 222 is in one embodiment a second TEOS layer. Then, an etch-stop layer 224 was deposited and structured. The etch-stop layer 224 is in one embodiment made of silicon nitride and deposited using low-pressure (LP)CVD. A galvanic contact 226 and a capacitor contact 228 were then formed. The galvanic contact 226 is in direct contact with the resonating beam 220, while the capacitive contact 228 is separated from the resonating beam by the upper release isolation layer 222 at the processing stage shown in FIG. 19.

The device structure of the MEMS device 218 was finished by standard backend processing, which is not described herein further detail. At the processing stage shown in FIG. 19, an insulating cover layer 230, contact elements 232 to 236, and a contact-isolation layer 238 have been deposited on the first integration-substrate side 210.

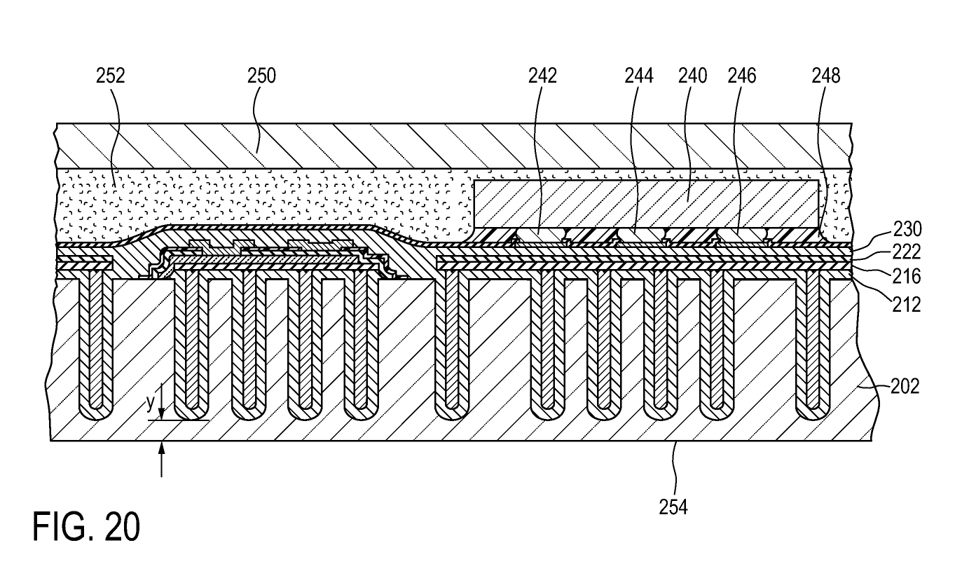

The further processing of the device will in the following be described with reference to FIGS. 20 to 29.

A first chip 240 comprising integrated circuits useful for the operation of the device is attached and electrically connected to the integration substrate 202 on its first integration-substrate side 210 by means of solder bumps 242 to 246, and an underfill 248. The active die 240 is thinned to a thickness of 20 to 30 μm.

After thinning of the first chip 240, a glass support substrate 250 is attached to the integration substrate 202. The glass substrate 250 can be glued to the integration substrate 202 by means of an adhesive layer 252. Suitably, a top-side-down gluing method is performed as an alternative to this support structure an epoxy over-mold can be applied on the first integration-substrate side. Note that the processing has been performed on a wafer level, and not on the individual chips.

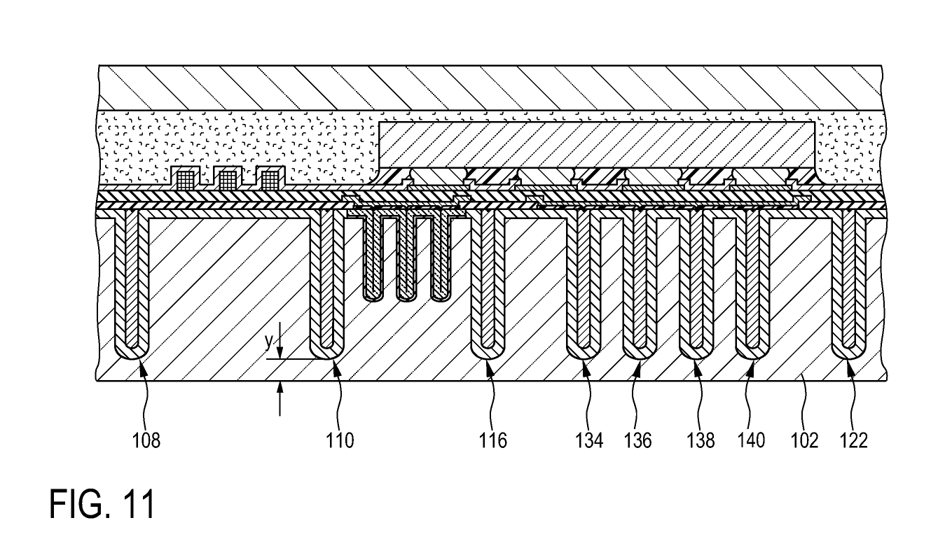

In a next step, the integration substrate 202 is thinned from its second integration substrate side 254. The details of the thinning step have been described in the context of the previous embodiment with reference to FIG. 11. The distance y between the bottom of the trenches 204, 206, and 208, and the surface of the second integration substrate side 254 amounts to approximately 20 μm after the thinning step. This processing stage is shown in FIG. 20.

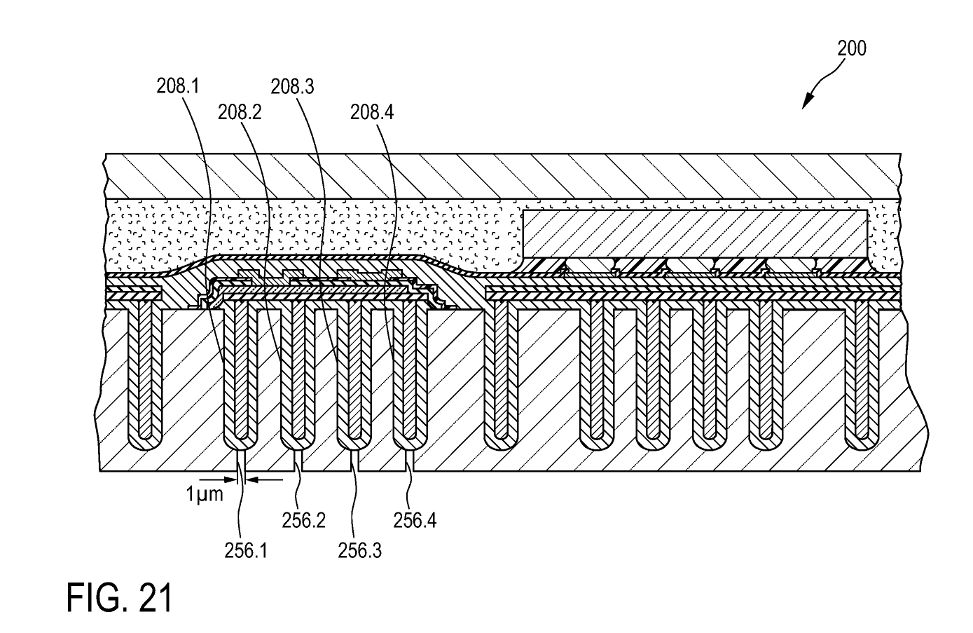

Turning now to FIG. 21, access trenches 256.1 to 256.4 are fabricated at the second integration-substrate side 254 by reactive ion etching. The etching stops at the trench isolation layer 212 of the release trenches 208.1 to 208.4. The width of the access trenches is approximately 1 μm.

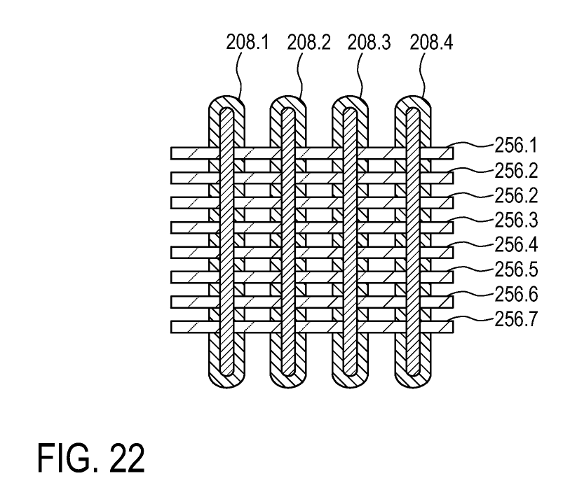

Precise alignment of the release trenches 208.1 to 208.4 is a critical issue at this step. As can be seen from FIG. 22, in one embodiment alignment errors of the access trenches with respect to the lateral position of release trenches 208′.1 to 208′.4 can be avoided by letting access trenches 256′.1 to 256′.4 run perpendicular to the release trenches. This forms an alternative arrangement to that shown in FIG. 21. Therefore, reference labels are used in FIG. 22, which correspond to those of FIG. 21 but have an inverted comma for the respective release and access trenches.

Returning to the processing stage of FIG. 21, the access trenches 256.1 to 256.4 are then used in a partial release etching to remove a large fraction of the trench insulation layer 212 from the release trenches 208.1 to 208.4. The etching can be performed using HF.

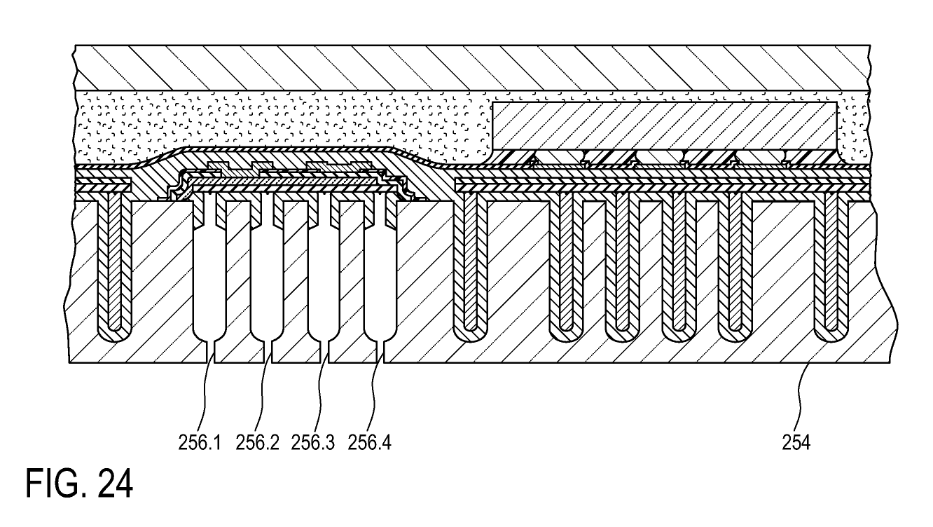

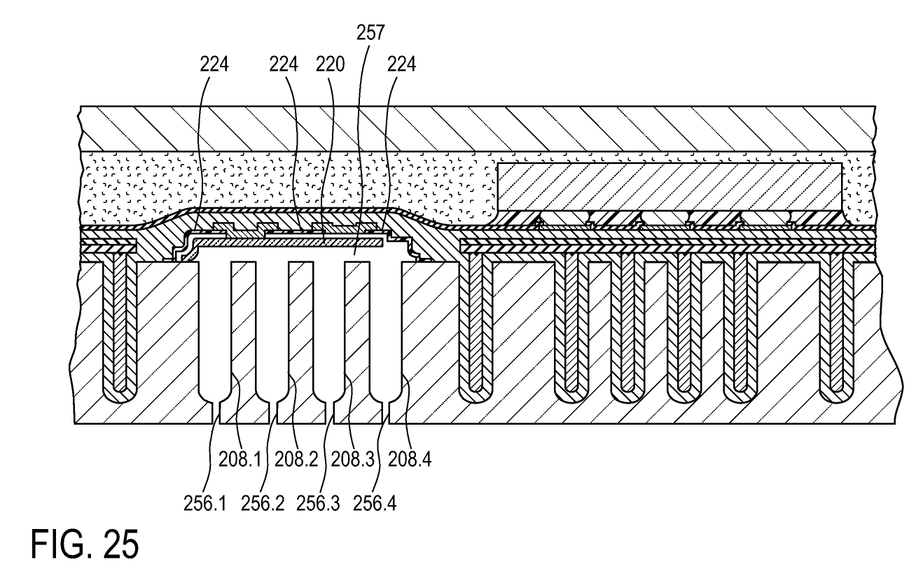

After this, as can be seen in FIG. 24, the tungsten via cores of the release trenches 208.1 to 208.4 are removed. This can be performed by dissolution of tungsten in NH₄OH/H₂O₂. The remaining trench insulation layer 212 and the dielectric layer 216 and upper release isolation layer 222 are removed in a following etch step. The removal can be achieved by means of HF. The etching stops at the poly-silicon and the silicon-nitride surfaces of the beam 220 and the etch-stop layer 224, respectively, thus defining a total release area. The release trenches 208.1 to 208.4 thus form sections of a cavity 257, in which the resonating beam 220 is arranged (FIG. 25).

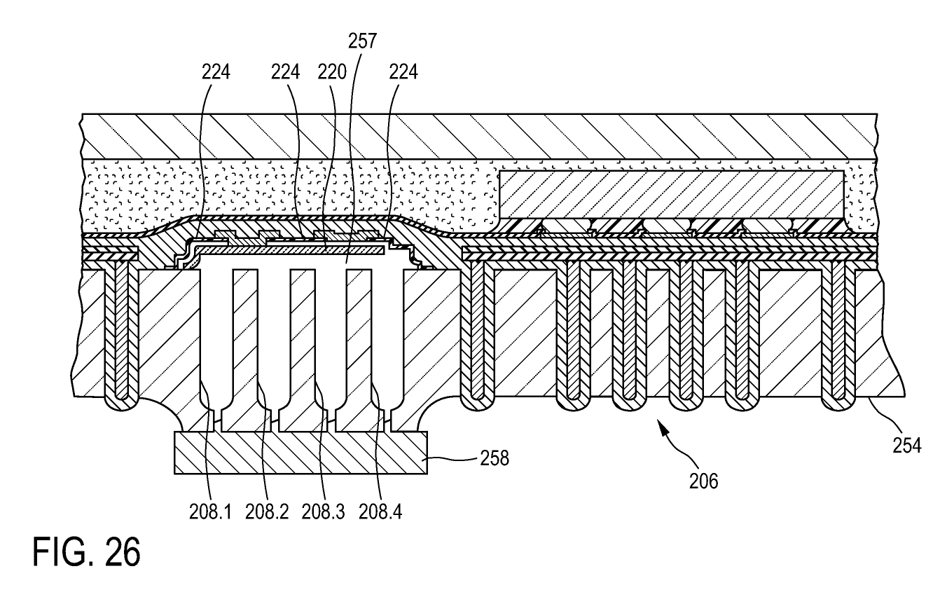

The structure is then dried, for instance by critical-point drying, and the access and release trenches are sealed on the second integration substrate side 254 with a resist plug 258 (FIG. 26). Furthermore, the silicon integration substrate 202 is thinned to expose the bottom areas of the isolation trenches 204 and the trench array 206. This can be performed by dry-etching of the silicon from the second integration-substrate side 254, for instance using a CF₄ barrel etch.

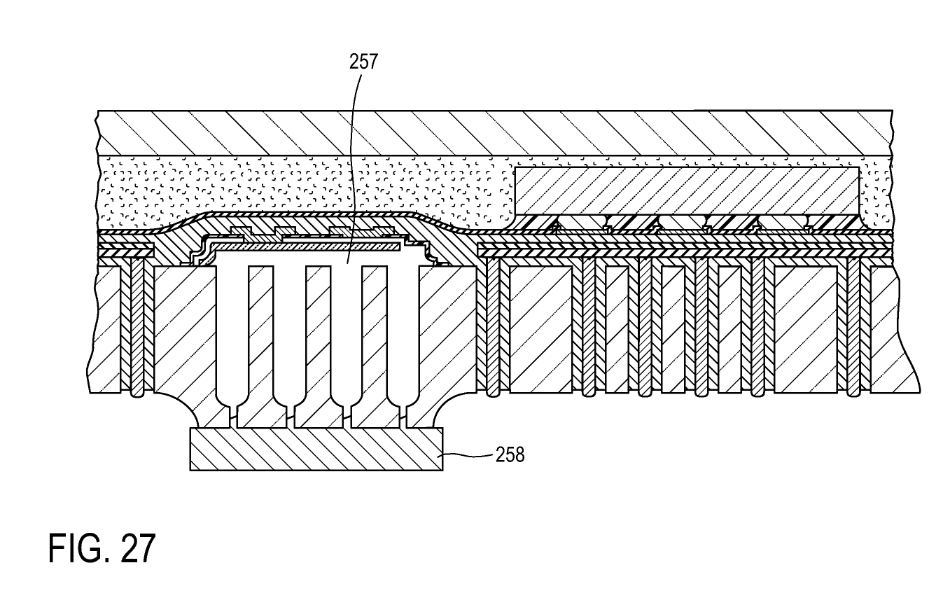

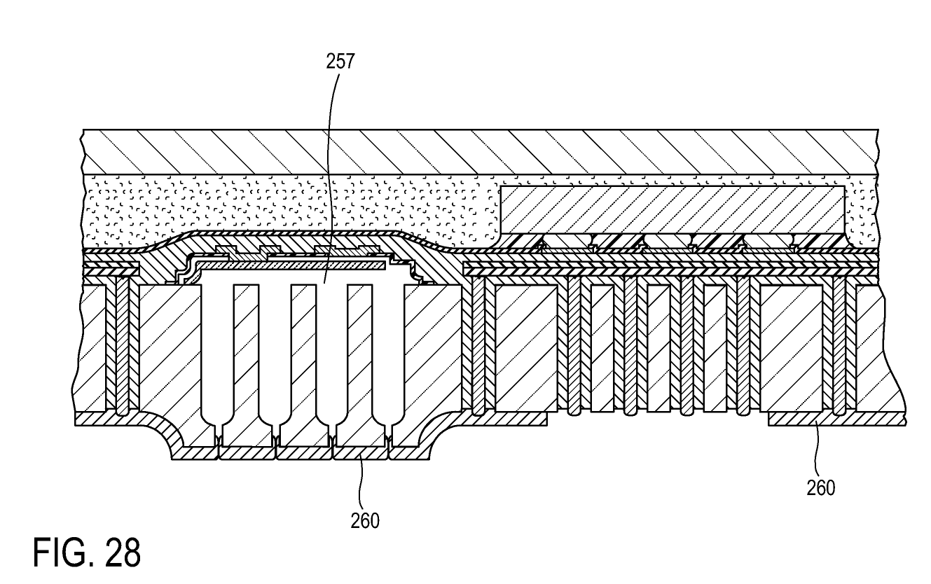

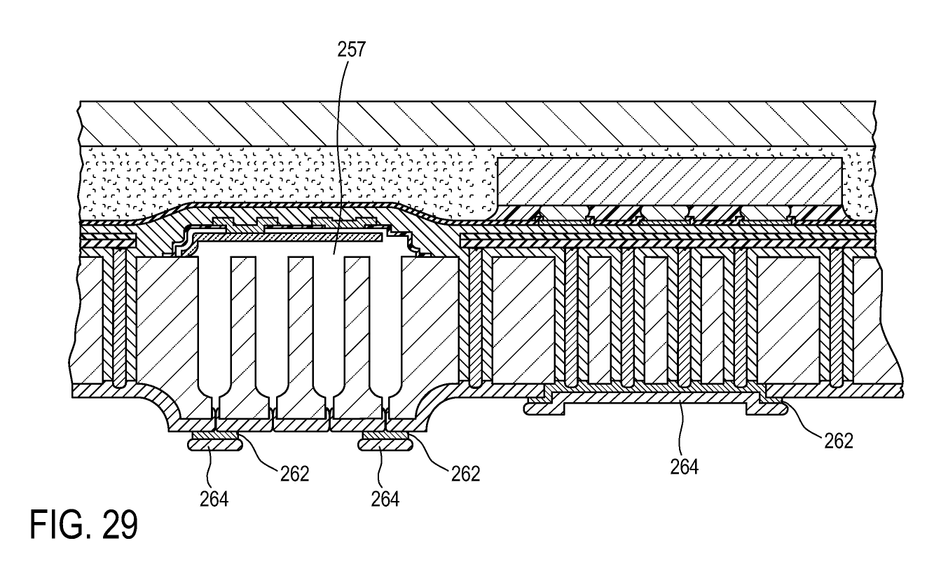

As has been described in the context of the first embodiment, the exposed bottom sections of the trench isolation layers are then removed by wet etching, as can be seen in FIG. 27. The resist plug 258 is subsequently stripped, followed by a deposition of a backside dielectric layer 260 (FIG. 28). The backside dielectric layer 260 serves at the same time as a seal for the release trenches 208.1 to 208.4 of the cavity 257, which have a reduced pressure, which for instance amounts to 1 to 5 mbar (FIG. 28). Then, as is shown in FIG. 29, a backside metallization 262 and an under-bump metallization 264 are applied. This is followed by attaching a second chip 266 to the under-bump metallization in the region of the MEMS device 218, and the fabrication of a solder ball 268 under the through-substrate via array 206. The second chip is attached also by means of an underfilling 270.

The processing described allows the fabrication of systems-in-package on a wafer scale. The systems-in-package contain vacuum-sealed cavities, namely, the release trenches 208. The processing allows using front-end processing steps. Regarding the release etch performed in the described processing, it should be considered that a release etch from the second integration-substrate side, which was also referred to as the backside of the wafer herein above, should be left intact and that only the access trenches 256.1 and 256.4 are used for the release etch.

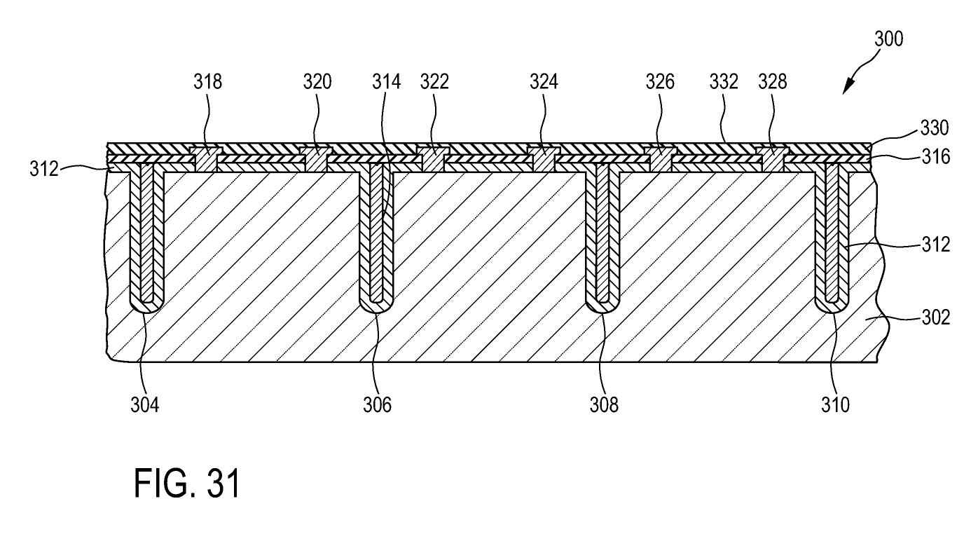

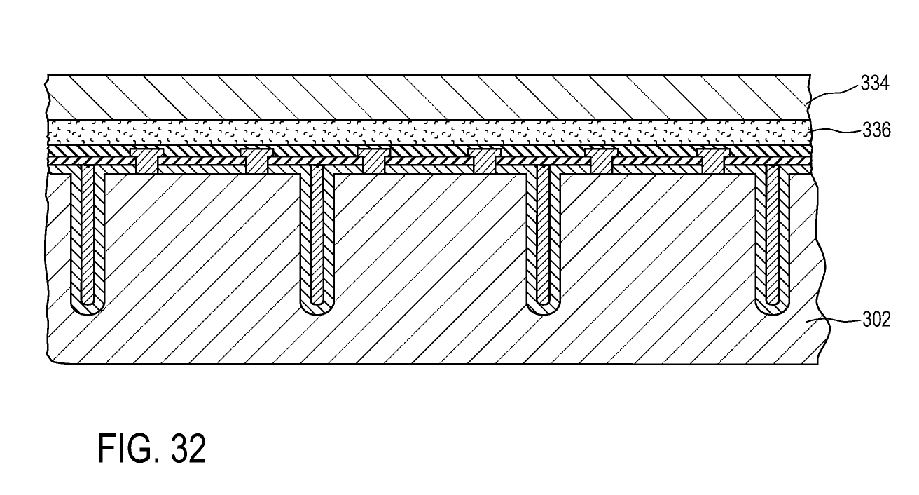

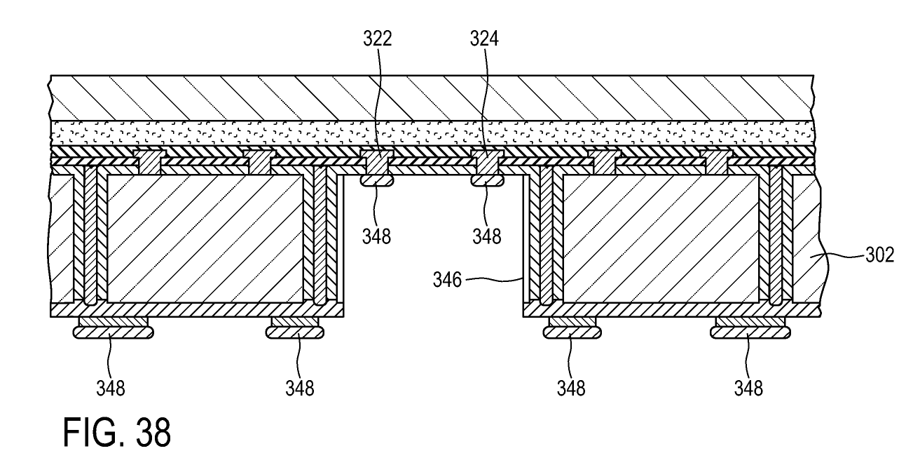

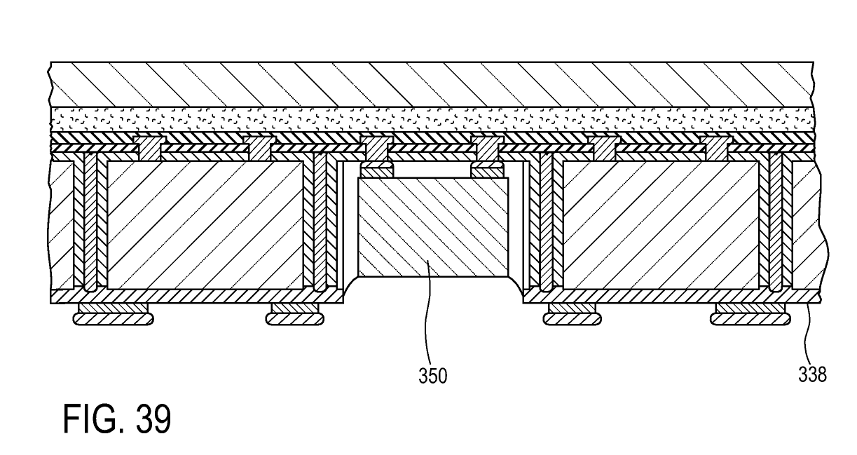

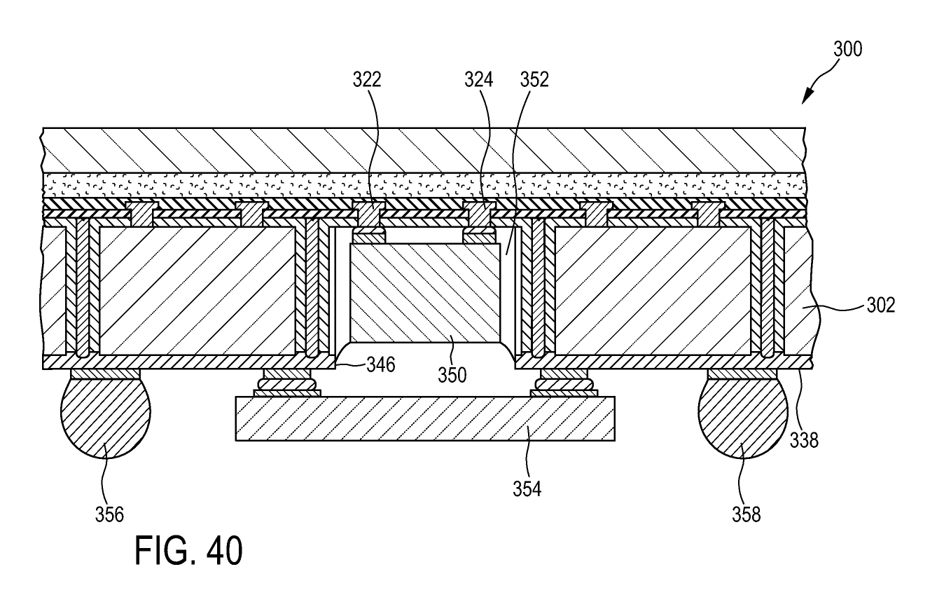

FIGS. 31 to 39 show schematic, cross-sectional views of a system-in-package during different stages of a third embodiment of a fabrication method. FIG. 40 shows a schematic cross-sectional view of a system-in-package according to a third embodiment.

FIG. 31 shows an integration substrate 302 for a system-in-package 300. In the integration substrate 302, trenches 304 to 310 have been fabricated in a manner corresponding to that described previously with reference to the first and second embodiments. As before, the trenches contain a trench isolation layer 312 and a tungsten core, which is by way of example pointed out by reference label 314. On top of the trench isolation layer, a dielectric layer 316 has been deposited. Metal contacts 318 to 328 have been formed, which extend down to the silicon substrate material of the integration substrate 302. A second dielectric layer 330 is shown in FIG. 31 without further detail. However, at this point of the processing, a first chip may have been connected and attached to the integration substrate 302 on its first integration substrate side 332 using some of the metal contacts 318 to 328. This processing has been described in detail in the framework of the previous embodiments and is not repeated here and also not shown for reasons of simplicity of the graphical representation.

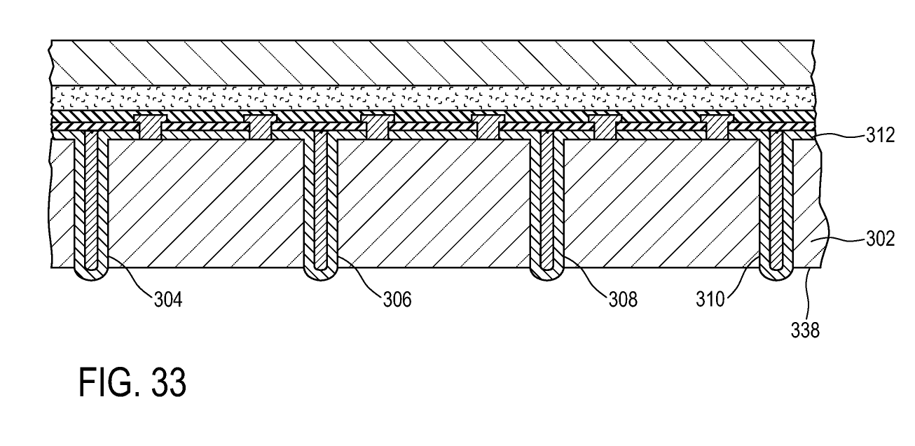

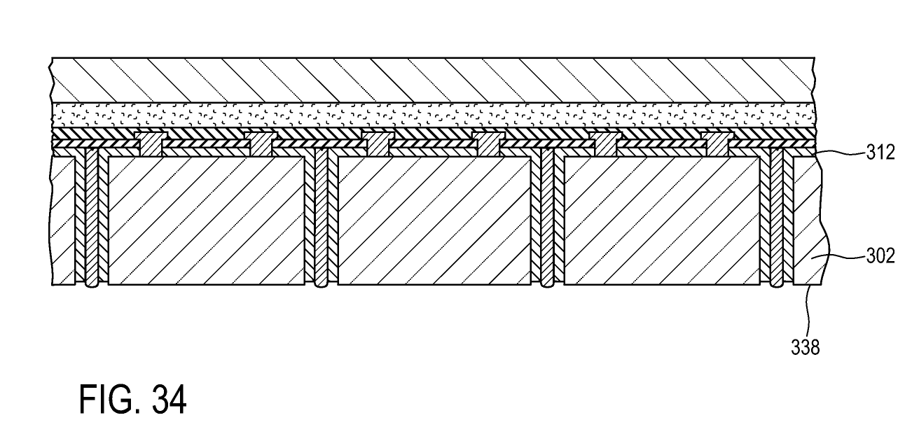

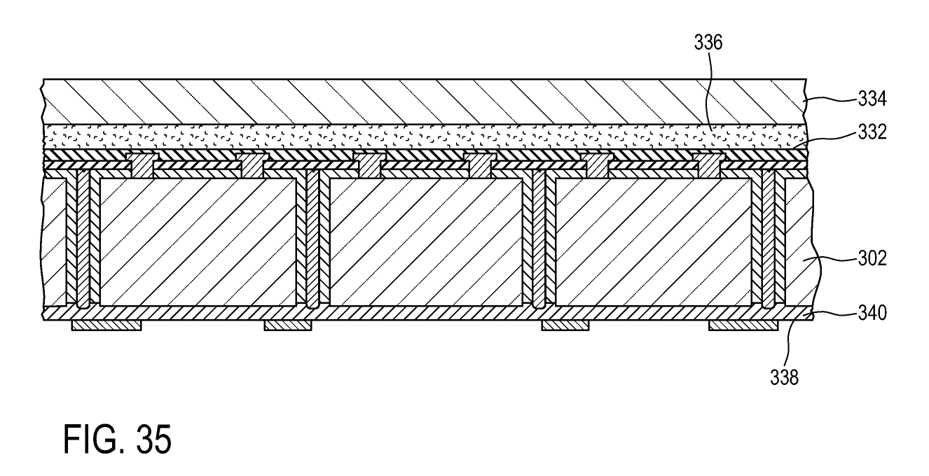

In a subsequent processing step, a support substrate 334 is attached to the integration substrate 302 on its first integration-substrate side by means of an adhesive layer 336. As before, a molding forms an alternative embodiment. The substrate is subsequently thinned on its second integration-substrate side 338 by the two-step processing described earlier. In the processing stage shown in FIG. 33, bottom regions of the trench isolation layer 312 at the trenches 304 to 310. The exposed trench-insulation-layer sections on the second integration-substrate side 338 are then removed, as described before, see FIG. 34. Subsequently, as can be seen in FIG. 35, a backside insulation layer 340 is applied on the second integration-substrate side 338, and a desired metallization scheme is fabricated. Note that FIG. 35 shows a simplified structure that does not contain any connections between the first and second integration substrate sides 332 and 338. However, this of course may apply only in a lateral section of the integration substrate 302, depending on the specific application of the system-in-package 300 to be formed. It is understood that through-substrate vias for electrically connecting conductive elements, circuit elements or integrated circuits, or chips arranged on the first and second integration-substrate sides. As described before, the trenches 304 to 310 may also serve for providing an electrical insulation of integration-substrate sections, depending on the needs of the specific application. Also, the through-substrate-vias may be used for transporting heat from one integration-substrate side to the other.

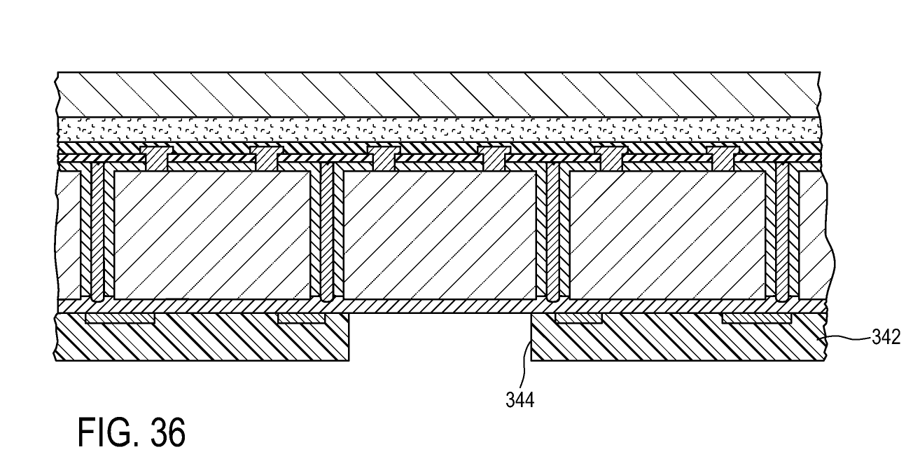

In a subsequent processing step, the result of which is shown in FIG. 36, a resist layer 342 is deposited and patterned. The patterning has resulted in an opening 344.

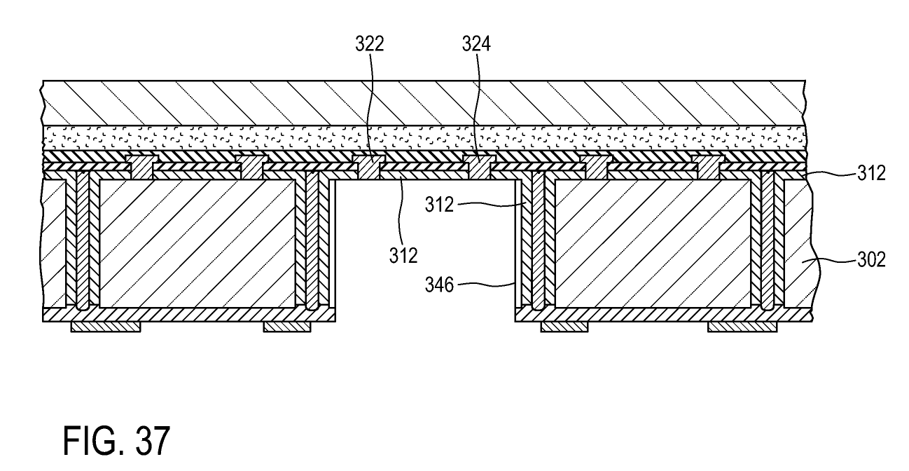

A deep reactive ion etching of integration-substrate material is then performed in the opening 344 of the resist layer 342 to fabricate an integration-substrate opening 346. The deep RIE process stops on the trench isolation layer 312, which is typically a silicon dioxide layer, and on the contacts 322 and 324, which may for instance be made from aluminum. The resist layer 342 is then removed to reach the intermediate processing stage shown in FIG. 37.

After that, an under-bump metallization 348 is applied to the backside metallization contacts and to the contacts 322 and 324. Here, a suitable electrodeless process can be used.

In a subsequent processing step, a second chip 350 is arranged and attached to the integration substrate in the opening 346. The second chip is connected with the integration substrate electrically by means of the contacts 322 and 324. An underfill 352 is provided between the second chip 350 and the sidewalls of the opening 346 of the integration substrate 302. Finally, a third chip 354 is attached and electrically connected to the integration substrate 302. In the present embodiment, the second chip is arranged to cover the opening 346 that contains the second chip 350. Note that instead of the third chip 354, an optical element such an active optical element like a light-emitting diode, or a passive optical element, such as a lens may be arranged on the second integration-substrate side 338.

In addition, solder balls 356 and 358 are fabricated, finishing the processing of the present embodiment.

The system-in-package 300 of FIG. 40 can for instance be used for the fabrication of radio frequency (RF) modules at very high frequencies. By arranging the second chip 350 inside the integration substrate 302, which typically contains passive elements, high-frequency connections between the active circuitry on the first chip on the first integration substrate side (not shown here for reasons of simplicity as explained above), the second chip 350 and the third chip 354 can be made in the same plain, thereby minimizing signal degradation.

Furthermore, the present embodiment allows a very high level of integration of integrated circuits by enabling the provision of chips, which are connected with the integration substrate 302, on three different levels.

In case it is not desired that the dry etch should end on the metal contacts 322 and 324, additional layers may be used to device an alternative self-aligned procedure, which was earlier described in U.S. Pat. No. 5,504,036.

While the invention has been illustrated and described in detail in the drawings and foregoing description, such illustration and description are to be considered illustrative or exemplary and not restrictive; the invention is not limited to the disclosed embodiments.

For instance, the combination of the aspect ratio of the through-substrate vias and of the thickness of the integration substrate is in some embodiments optimized according to the requirements of the specific application with regard to integration density and lead inductance. Increasing the integration density on the integration substrate includes the possibility of providing a larger number of through-substrate vias at different positions, without increasing area consumption on the integration substrate. Having through-substrate vias distributed over the integration substrate allows reducing the length of conductive lines leading to and from the through-substrate vias. Where a particularly low resistance of a through-substrate via is required, several individual through-substrate vias can be electrically connected and used in parallel.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

Any reference signs in the claims should not be construed as limiting the scope.

1. A system-in-package, comprising:
an integration substrate (with a thickness of less than 100 micrometers and including a first plurality of through-substrate vias, which have an electrically conductive via core and an aspect ratio larger than 5, and which are configured to electrically connect a first conductive element on a first integration-substrate side with a second conductive element on a second integration-substrate side;
a support, which is attached to the integration substrate on its first integration-substrate side and which is suitable for mechanically supporting the integration substrate; and
a first chip, which is attached and electrically connected to the integration substrate either on its first integration-substrate sided, where it is either arranged between the integration substrate and the support or where it forms the support, or
a second chips, which is attached and electrically connected to the integration substrate on its second integration-substrate side.

2. The system-in-package of claim 1, wherein the aspect ratio of the through-substrate vias is between 15 and 25.

3. The system-in-package of claim 1, wherein the integration substrate has a thickness between 15 and 40 Micrometers.

4. The system-in-package of claim 1, comprising a second plurality of trench structures in the integration substrate, which in comparison with the through-substrate vias have smaller depth extensions.

5. The system-in-package of claim 1, comprising at least one trench structure in the integration substrate, which has the same depth extension as the through-substrate vias.

6. The system-in-package of claim 5, wherein the trench structure, as seen in a top view from the first integration-substrate side, has a ring shape.

7. The system-in-package of claim 5, wherein the trench structure forms a section of a cavity in the integration substrate.

8. The system-in-package of claim 1, wherein the through-substrate vias have a via-insulation layer, which is arranged to prevent a direct electrical connection between the via core and the integration substrate.

9. The system-in-package of claim 1, wherein a subset of the first plurality of through-substrate vias is electrically connected to a single contact element on the second integration-substrate sided.

10. The system-in-package of claim 1, comprising an opening in the integration substrate that is open to the second integration-substrate side.

11. The system-in-package of claim 10, wherein a third chip is arranged in the opening.

12. A system-in-package, comprising:
an integration substrate with a thickness of less than 100 micrometers and including through-substrate vias that have an electrically conductive via core, of which vias a first number are configured to electrically connect a first conductive element on the first integration-substrate side with a second conductive element on the second integration-substrate side and of which vias at least one second via is configured to constitute a lateral enclosure for a first portion of the integration substrate;
a support, which is attached to the integration substrate on its first integration-substrate side and which is suitable for mechanically supporting the integration substrates; and
a first chip, which is attached and electrically connected to the integration substrate either on its first integration-substrate side, where it is either arranged between the integration substrate and the support or where it forms the support, or a second chip, which is attached and electrically connected to the integration substrate on its second integration-substrate side.

13. The system-in-package of claim 12, wherein the trench structures are provided with an electrically insulating side wall and the lateral enclosure is configured to electrically isolate the first portion.

14. The system-in-package of claim 13, wherein the lateral enclosure forms at least a part of an electrical shield for a component in or on the first portion of the integration substrate.

15. A system-in-packages, comprising:
an integration substrate with a thickness of less than 100 micrometers and including a first plurality of through-substrate vias, that have an electrically conductive via core, of which vias a first plurality are configured to electrically connect a first conductive element on the first integration-substrate side with a second conductive element on the second integration-substrate side;
at least one access channel to a cavity that is defined at and/or on the first integration-substrate side, said access channel extending from the second integration-substrate side parallel to said through-substrate vias;
a support, which is attached to the integration substrate on its first integration-substrate side and which is suitable for mechanically supporting the integration substrate; and
a first chip, which is attached and electrically connected to the integration substrate on its first integration-substrate side, where it is either arranged between the integration substrate and the support or where it forms the support, or a second chip, which is attached and electrically connected to the integration substrate on its second integration-substrate side.

16. A method for fabricating a system-in-package, comprising:
providing an integration substrate of a thickness, the integration substrate having a first integration-substrate side and a second integration-substrate side and trench structures, such that in the integration substrate of the finished system-in-package an aspect ratio of the through-substrate vias fabricated from the trench structures is larger than 5, a first plurality of which trench structures is provided with an electrically conductive via core;
attaching a support, which is suitable for mechanically supporting the integration substrate at a reduced integration-substrate thickness of less than 100 micrometers, to the integration substrate on its first integration substrate side;
reducing the thickness of the integration substrate from its second integration-substrate side to a thickness below 100 micrometers, such that only a bottom face of the via cores of the via trench structures is exposed;
electrically connecting and attaching a first chip to the integration substrate on its first integration-substrate side, such that the first chip is arranged between the integration substrate and the support, or electrically connecting and attaching a second chip to the integration substrate on its second integration-substrate side.

17. The method of claim 16, comprising:
a fabrication of a second plurality of trench structures in the integration substrate with a smaller depth extension in comparison with a depth extension of the first plurality of trench structures, by reactive ion etching,
wherein the first and second plurality of trench structures are etched concurrently and etching comprises forcing smaller lateral extensions for the second plurality of trench structures than for the first plurality of trench structures.

18. The method of claim 16, wherein thinning the integration substrate comprises:
mechanically grinding the integration substrate from the second integration-substrate side to a thickness that just avoids exposure of the first plurality of trenches;
spin-etching the integration substrate using a first etching agent that leaves the via insulation layer intact;
removing a part of the via-insulation layer by etching, using a second etching agent that leaves the via core intact.

19. The method of claim 16, comprising:
attaching the first chip on the first integration-substrate side of the integration substrate before attaching the supports, and
thinning the first chip before attaching the support.

20. The method of claim 16, wherein attaching the support comprises:
depositing an adhesive layer that can be cured by irradiation with ultraviolet light on the first integration-substrate side;
positioning the support on the adhesive layer;
irradiating the adhesive layer with ultraviolet light.

21. The method of claim 16, comprising a step of fabricating an opening in the integration substrate that is open on the second integration-substrate side.

22. The method of claim 16, comprising a step of attaching and electrically connecting a third chip to the integration substrate in the openings.

23. The method of claim 16, wherein:
providing the integration substrate comprises providing an integration-substrate assembly with the integration substrate having an integration-substrate thickness below 100 micrometers and a temporary support attached thereto; and
reducing the thickness of the integration substrate from its second integration-substrate side to a thickness below 100 micrometers comprises removing the temporary support.

24. A method for manufacturing a system-in-package, comprising the steps of:
providing an integration substrate having a first integration-substrate side and a second integration-substrate side and a thickness and comprising a first plurality of trench structures and a second set of at least one trench structure, all of which trench structures are provided with an electrically conductive via core, of which the first plurality of trench structures is configured for a signal transmission function and of the which second set of trench structures is configured for another function, which is one of a heat dissipation, grounding, lateral enclosure of a first portion of the integration substrate, and constituting at least one access channel for a cavity to be created by removal of a sacrificial layer through said access channel;
attaching a support, which is suitable for mechanically supporting the integration substrate at a reduced integration-substrate thickness of less than 100 micrometers, to the integration substrate on its first integration substrate side;
reducing the thickness of the integration substrate from its second side to a thickness below 100 micrometers, such that only a bottom face of the via cores of the second plurality of trench structures is exposed;
electrically connecting and attaching a first chip to the integration substrate on its first integration-substrate side, such that the first chip is arranged between the integration substrate and the support, or electrically connecting and attaching a second chip to the integration substrate on its second integration-substrate side.

25. An integration substrate including trenches that have an electrically conductive trench core, of which trenches a first plurality are electrically connected with a first conductive element on the first integration-substrate, and of which trenches at least one second trench is configured to constitute a lateral enclosure for a first portion of the integration substrate.
